(19) United States
(12) Patent Application Publication
(10) Pub. No.: US 2022/0137509 A1
(43) Pub. Date: May 5, 2022

(54) PHOTORESIST COMPOSITIONS AND PATTERN FORMATION METHODS

(71) Applicant: Rohm and Haas Electronic Materials LLC, Marlborough, MA (US)

(72) Inventors: Xisen Hou, Lebanon, NH (US); Mingqi Li, Shrewsbury, MA (US); Joshua Kaitz, Shrewsbury, MA (US); Tomas Marangoni, Marlborough, MA (US); Peter Trefonas, III, Medway, MA (US)

(21) Appl. No.: 17/506,082

(22) Filed: Oct. 20, 2021

Related U.S. Application Data
(60) Provisional application No. 63/108,342, filed on Oct. 31, 2020.

(51) Int. Cl. G03F 7/038; G03F 7/004; G03F 7/38; G03F 7/40; G03F 7/20

(52) U.S. Cl. CPC G03F 7/038; G03F 7/0045; G03F 7/20; G03F 7/40; G03F 7/38

(57) ABSTRACT

Photoresist compositions comprise: an acid-sensitive polymer comprising a first repeating unit formed from a first free radical polymerizable monomer comprising an acid-decomposable group and a second repeating unit formed from a second free radical polymerizable monomer comprising a carboxylic acid group; a compound comprising two or more enol ether groups, wherein the compound is different from the acid-sensitive polymer; a material comprising a base-labile group; a photoacid generator; and a solvent. The photoresist compositions and pattern formation methods using the photoresist compositions find particular use in the formation of fine lithographic patterns in the semiconductor manufacturing industry.

### BACKGROUND OF THE INVENTION

### 1. Field of the Invention

The invention relates generally to the manufacture of electronic devices. More specifically, this invention relates to photoresist compositions and to pattern formation methods using such compositions. The compositions and methods find particular use in the formation of lithographic patterns useful in the manufacture of semiconductor devices.

### 2. Description of the Related Art

In the semiconductor manufacturing industry, photoresist layers are used for transferring an image to one or more underlying layers, such as metal, semiconductor or dielectric layers, disposed on a semiconductor substrate, as well as to the substrate itself. To increase the integration density of semiconductor devices and allow for the formation of structures having dimensions in the nanometer range, photoresist compositions and photolithography processing tools having high-resolution capabilities have been and continue to be developed.

Chemically amplified photoresist compositions are conventionally used for high-resolution processing. Such compositions typically employ a polymer having acid-decomposable groups, a photoacid generator (PAG), and a solvent. Pattern-wise exposure of a layer formed from such photoresist composition to activating radiation causes the acid generator to form an acid which, during post-exposure baking, causes cleavage of the acid-decomposable groups in exposed regions of the photoresist layer. This creates a difference in solubility characteristics between exposed and unexposed regions of the layer in a developer solution. In a positive tone development (PTD) process, exposed regions of the photoresist layer become soluble in aqueous base developer and are removed from the substrate surface, and unexposed regions, which are insoluble in the developer, remain after development to form a positive image. The resulting relief image permits selective processing of the substrate.

One approach to achieving nm-scale feature sizes in semiconductor devices is the use of short wavelengths of light, for example, 193 nanometers (nm) or less, during exposure of chemically amplified photoresists. To further improve lithographic performance, immersion lithography tools have been developed to effectively increase the numerical aperture (NA) of the lens of the imaging device, for example, an immersion scanner having an ArF (193 nm) light source. This is accomplished by use of a relatively high refractive index fluid, typically water, between the last surface of the imaging device and the upper surface of the semiconductor wafer. ArF immersion tools are currently pushing the boundaries of lithography to the 16 nm and 14 nm nodes with the use of multiple (double or higher order) patterning. However, with increases in lithographic resolution, linewidth roughness (LWR) of the photoresist patterns has become of greater importance in creating high-resolution patterns. Excessive linewidth variation along the length of a gate, for example, can have adverse consequences on threshold voltage and may increase leakage current, both of which can adversely impact device performance and yield. Photoresist compositions allowing for desired LWR characteristics would therefore be desired.

Process throughput is an area of great interest in the semiconductor manufacturing industry. This is particularly true for the photoresist exposure process given the high frequency with which it appears throughout device formation. Advanced photoresist exposure tools typically move across the wafer, exposing the photoresist layer one die at a time. The time to process all die across a wafer can be significant. Photoresist compositions having improved photosensitivity would allow for a target critical dimension (CD) to be achieved with a lower exposure time. Photoresist compositions of improved sensitivity would therefore be desired.

U.S. Application Pub. No. US2006/0160022A1 discloses chemically-amplified positive photoresist compositions that contain a cross-linked resin. The cross-linked resin contains a polymerized unit formed from a monomer that functions as the crosslinker. That polymerized unit contains two acetal groups which are intended to decompose after exposure and during post-exposure bake by reaction with photo-generated acid, thereby rendering the exposed regions of the photoresist layer soluble in an aqueous developer. Such photoresist compositions are believed to exhibit shelf-life stability issues and can also be a challenge to make due to the relative instability of acetal groups during synthesis. A more stable photoresist composition would therefore be desired.

There is thus a need in the art for improved photoresist compositions and pattern formation methods which address one or more problems associated with the state of the art.

### SUMMARY OF THE INVENTION

In accordance with a first aspect of the invention, photoresist compositions are provided. The photoresist compositions comprise: an acid-sensitive polymer comprising a first repeating unit formed from a first free radical polymerizable monomer comprising an acid-decomposable group and a second repeating unit formed from a second free radical polymerizable monomer comprising a carboxylic acid group; a compound comprising two or more enol ether groups, wherein the compound is different from the acid-sensitive polymer; a material comprising a base-labile group; a photoacid generator; and a solvent.

Also provided are pattern formation methods. The pattern formations methods comprise: (a) applying a layer of a photoresist composition as described herein on a substrate; (b) soft-baking the photoresist composition layer; (b) exposing the soft-baked photoresist composition layer to activating radiation; (d) post-exposure baking the photoresist composition layer; and (c) developing the post-exposure baked photoresist composition layer to provide a resist relief image.

### DETAILED DESCRIPTION OF THE INVENTION

The terminology used herein is for the purpose of describing particular embodiments only and is not intended to be limiting of the invention. The singular forms “a”, “an” and “the” are intended to include singular and plural forms, unless the context indicates otherwise. All ranges disclosed herein are inclusive of the endpoints, and the endpoints are independently combinable with each other. When an element is referred to as being “on” or “over” another element, it may be directly in contact with the other element or intervening elements may be present therebetween. In contrast, when an element is referred to as being “directly on” another element, there are no intervening elements present.

As used herein, an “acid-decomposable group” refers to a group in which a bond is cleaved by the catalytic action of an acid, optionally and typically with thermal treatment, resulting in a polar group, for example, a carboxylic acid or an alcohol group, being formed on the polymer, and optionally and typically with a moiety connected to the cleaved bond becoming disconnected from the polymer. Acid-decomposable groups include, for example: tertiary alkyl ester groups, secondary or tertiary aryl ester groups, secondary or tertiary ester groups having a combination of alkyl and aryl groups, or tertiary alkoxy groups. Acid-decomposable groups are also commonly referred to in the art as “acid-cleavable groups,” “acid-cleavable protecting groups,” “acid-labile groups,” “acid-labile protecting groups,” “acid-leaving groups,” and “acid-sensitive groups.”

Unless otherwise indicated, a group that is “substituted” refers to a group having one or more of its hydrogen atoms replaced with one or more substituents. Exemplary substituent groups include, but are not limited to, hydroxy (—OH), halogen (e.g., —F, —Cl, —I, —Br), C₁₋₁₈ alkyl, C₁₋₈ haloalkyl, C₃₋₁₂ cycloalkyl, C₆₋₁₂ aryl having at least one aromatic ring (e.g., phenyl, biphenyl, naphthyl, or the like, each ring either substituted or unsubstituted aromatic), C₇₋₁₉ arylalkyl having at least one aromatic ring, C₇₋₁₂ alkylaryl, and combinations thereof. For purposes of carbon number determination, when a group is substituted, the number of carbon atoms of the group is the total number of carbon atoms in such group excluding those of any substituents.

The photoresist compositions of the invention include an acid-sensitive polymer, a compound comprising two or more enol ether groups, wherein the compound is different from the acid-sensitive polymer, a material comprising a base-labile group, a photoacid generator, and a solvent, and can include one or more optional additional components. The inventors have surprisingly discovered that particular photoresist compositions of the invention can achieve notably improved lithographic performance, such as reduced linewidth roughness (LWR) and improved photosensitivity.

The acid-sensitive polymer comprises a first repeating unit formed from a first free radical polymerizable monomer comprising an acid-decomposable group and a second repeating unit formed from a second free radical polymerizable monomer comprising a carboxylic acid group, and may include one or more additional types of repeating units. The polymer should have good solubility in the solvent of the photoresist composition.

The acid-decomposable group may be of a type which, on decomposition, forms a carboxylic acid group or an alcohol group on the polymer. The acid-decomposable group is preferably a tertiary ester group, and more preferably a tertiary alkyl ester group. Suitable repeating units having an acid-decomposable group may, for example, be derived from one or more monomers of formulas (1a), (1b), or (1d):

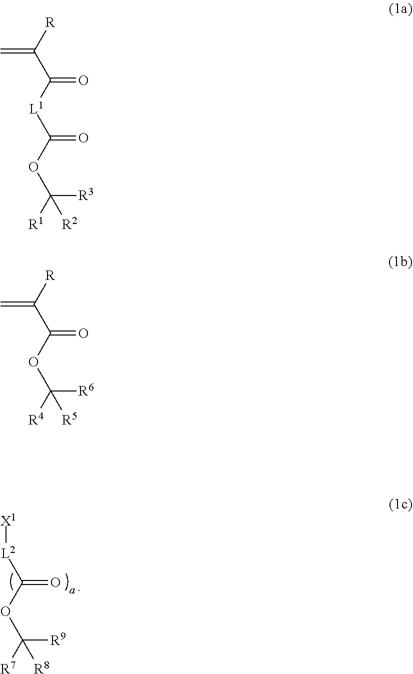

In formulas (1a) and (1b), R is hydrogen, fluorine, cyano, substituted or unsubstituted C₁₋₁₀ alkyl, or substituted or unsubstituted C₁₋₁₀ fluoroalkyl. Preferably, R is hydrogen, fluorine, or substituted or unsubstituted C₁₋₅ alkyl, typically methyl.

In formula (1a), L¹ is a divalent linking group including at least one carbon atom, at least one heteroatom, or a combination thereof. For example, L¹ may include 1 to 10 carbon atoms and at least one heteroatom. In a typical example, L¹ may be —OCH₂—, —OCH₂CH₂O—, or —N(R²¹)—, wherein R²¹ is hydrogen or C₁₋₆ alkyl.

In formulas (1a) and (1b), R¹ to R⁶ are each independently hydrogen, straight chain or branched C₁₋₂₀ alkyl, a monocyclic or polycyclic C₃₋₂₀ cycloalkyl, a monocyclic or polycyclic C₁₋₂₀ heterocycloalkyl, a straight chain or branched C₂₋₂₀ alkenyl, a monocyclic or polycyclic C₃₋₂₀ cycloalkenyl, a monocyclic or polycyclic C₃₋₂₀ heterocycloalkenyl, a monocyclic or polycyclic C₆₋₂₀ aryl, or a monocyclic or polycyclic C₂₋₂₀ heteroaryl, each of which except hydrogen is substituted or unsubstituted; provided that only one of R¹ to R³ can be hydrogen and only one of R⁴ to R⁶ can be hydrogen, and provided that when one of R¹ to R³ is hydrogen, one or both of the others of R¹ to R³ are a substituted or unsubstituted monocyclic or polycyclic C₆₋₂₀ aryl or a substituted or unsubstituted monocyclic or polycyclic C₄₋₂₀ heteroaryl, and when one of R⁴ to R⁶ is hydrogen, one or both of the others of R⁴ to R⁶ are a substituted or unsubstituted monocyclic or polycyclic C₆₋₂₀ aryl or a substituted or unsubstituted monocyclic or polycyclic C₄₋₂₀ heteroaryl. Preferably, R¹ to R⁶ are each independently a straight chain or branched C₁₋₆ alkyl, or a monocyclic or polycyclic C₃₋₁₀ cycloalkyl, each of which is substituted or unsubstituted.

In formula (1a), any two of R¹ to R³ together optionally form a ring, and each of R¹ to R³ optionally may include as part of their structure one or more groups chosen from —O—, —C(O)—, —C(O)—O—, —S—, —S(O)₂—, and —N(R⁴²)—S(O)₂—, wherein R⁴² may be hydrogen, a straight chain or branched C₁₋₂₀ alkyl, monocyclic or polycyclic C₃₋₂₀ cycloalkyl, or monocyclic or polycyclic C₁₋₂₀ heterocycloalkyl. In formula (2b), any two of R⁴ to R⁶ together optionally form a ring, and each of R⁴ to R⁶ optionally may include as part of their structure one or more groups chosen from —O—, —C(O)—, —C(O)—O—, —S—, —S(O)₂—, and —N(R⁴³)—S(O)₂—, wherein R⁴³ is hydrogen, a straight chain or branched C₁₋₂₀ alkyl, monocyclic or polycyclic C₃₋₂₀ cycloalkyl, or monocyclic or polycyclic C₁₋₂₀ heterocycloalkyl.

In formula (1c), R⁷ to R⁹ may be each independently hydrogen, straight chain or branched C₁₋₂₀ alkyl, a monocyclic or polycyclic C₃₋₂₀ cycloalkyl, a monocyclic or polycyclic C₁₋₂₀ heterocycloalkyl, a monocyclic or polycyclic C₆₋₂₀ aryl, or a monocyclic or polycyclic C₂₋₂₀ heteroaryl, each of which except hydrogen is substituted or unsubstituted, any two of R⁷ to R⁹ together optionally form a ring, and each of R⁷ to R⁹ optionally may include as part of their structure one or more groups chosen from —O—, —C(O)—, —C(O)—O—, —S—, —S(O)₂—, and —N(R⁴⁴)—S(O)₂—, wherein R⁴⁴ may be hydrogen, a straight chain or branched C₁₋₂₀ alkyl, monocyclic or polycyclic C₃₋₂₀ cycloalkyl, or monocyclic or polycyclic C₁₋₂₀ heterocycloalkyl; provided that only one of R⁷ to R⁹ can be hydrogen when the acid-decomposable group is not an acetal group, provided that when one of R⁷ to R⁹ is hydrogen, one or both of the others of R⁷ to R⁹ are a substituted or unsubstituted monocyclic or polycyclic C₆₋₂₀ aryl or a substituted or unsubstituted monocyclic or polycyclic C₄₋₂₀ heteroaryl.

In formula (1c), X¹ is a polymerizable group selected from vinyl and norbornyl; and L² is a single bond or a divalent linking group, provided that L² is not a single bond when X¹ is vinyl. Preferably, L² is a monocyclic or polycyclic C₆₋₃₀ arylene or a monocyclic or polycyclic C₆₋₃₀ cycloalkylene, each of which can be substituted or unsubstituted. In formula (1c), a is 0 or 1. It is to be understood that when a is 0, the L² group is connected directly to the oxygen atom.

Non-limiting examples of monomers (1a) include:

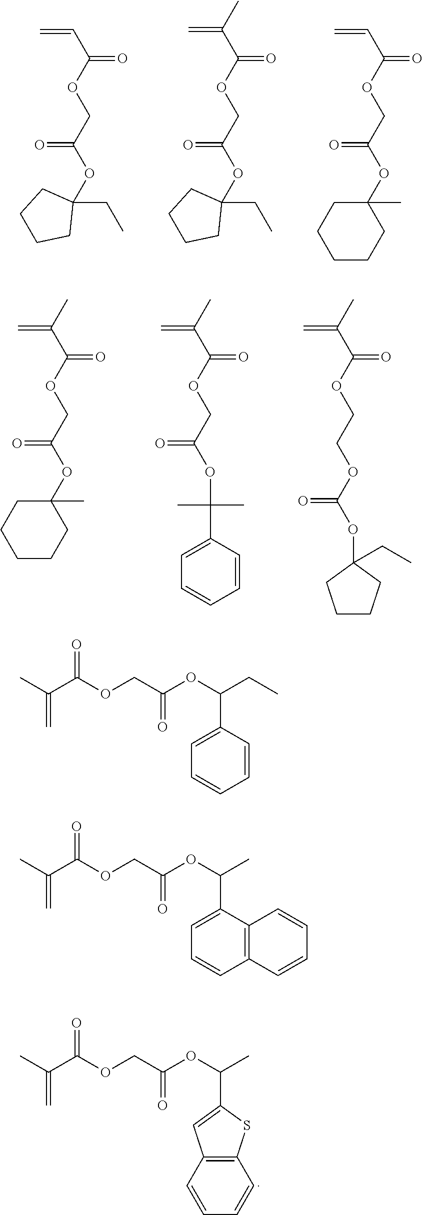

Non-limiting examples of monomers of formula (1b) include:

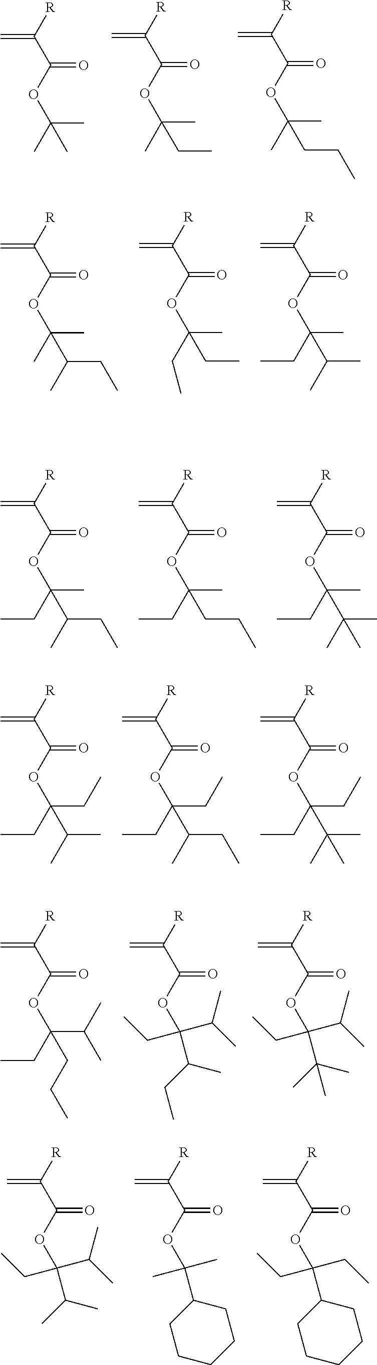

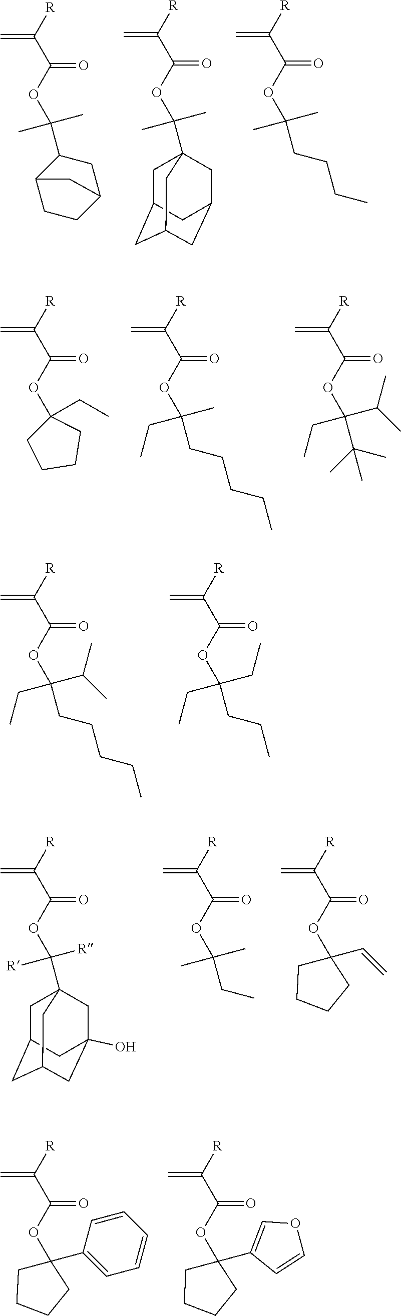

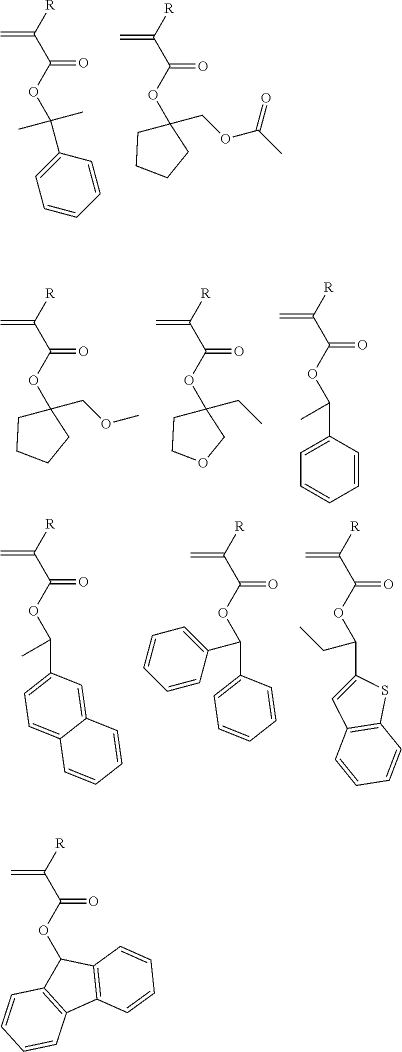

wherein R is as defined above; and R′ and R″ are each independently a straight chain or branched C₁₋₂₀ alkyl, a monocyclic or polycyclic C₃₋₂₀ cycloalkyl, a monocyclic or polycyclic C₁₋₂₀ heterocycloalkyl, a straight chain or branched C₂₋₂₀ alkenyl, a monocyclic or polycyclic C₃₋₂₀ cycloalkenyl, a monocyclic or polycyclic C₃₋₂₀ heterocycloalkenyl, a monocyclic or polycyclic C₆₋₂₀ aryl, or a monocyclic or polycyclic C₄₋₂₀ heteroaryl, each of which is substituted or unsubstituted.

Non-limiting examples of monomers (1e) include:

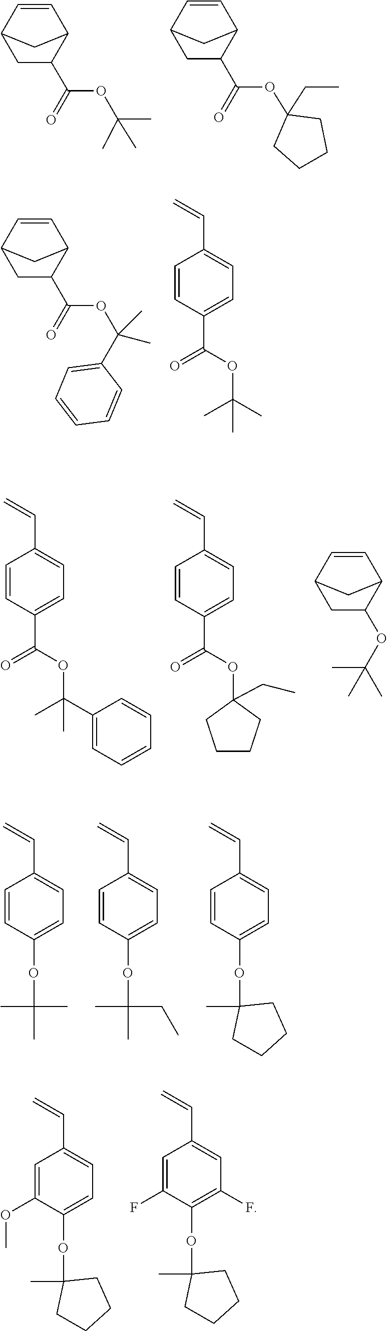

The repeating unit having an acid-decomposable group is typically present in the acid-sensitive polymer in an amount from 10 to 80 mol %, more typically from 25 to 75 mol %, still more typically from 30 to 70 mol %, based on total repeating units in the acid-sensitive polymer.

The second repeating unit of the acid-sensitive polymer is formed from a second free radical polymerizable monomer comprising a carboxylic acid group. Typically, the second repeating unit is of the formula (2):

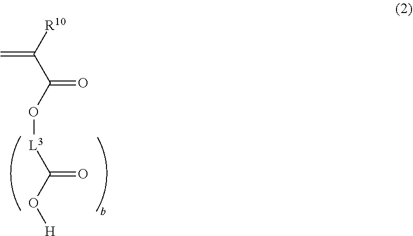

wherein: R¹⁰ is hydrogen, fluorine, substituted or unsubstituted C₁₋₁₀ linear, C₃₋₁₀ branched or C₃₋₁₀ cyclic alkyl, typically hydrogen or methyl; L³ is a divalent linking group comprising at least one carbon atom, for example, substituted or unsubstituted C₁₋₁₀ linear, C₃₋₁₀ branched, or C₃₋₁₀ cyclic alkylene, or a combination thereof, and may include one or more heteroatoms; and b is 0 or 1, with 0 being typical. R¹⁰ and L³ may optionally each independently as part of its structure one or more groups chosen from —O—, —C(O)—, —C(O)O— (e.g., —C(O)OH), or —S—.

Suitable monomers of formula (2) include, for example, the following:

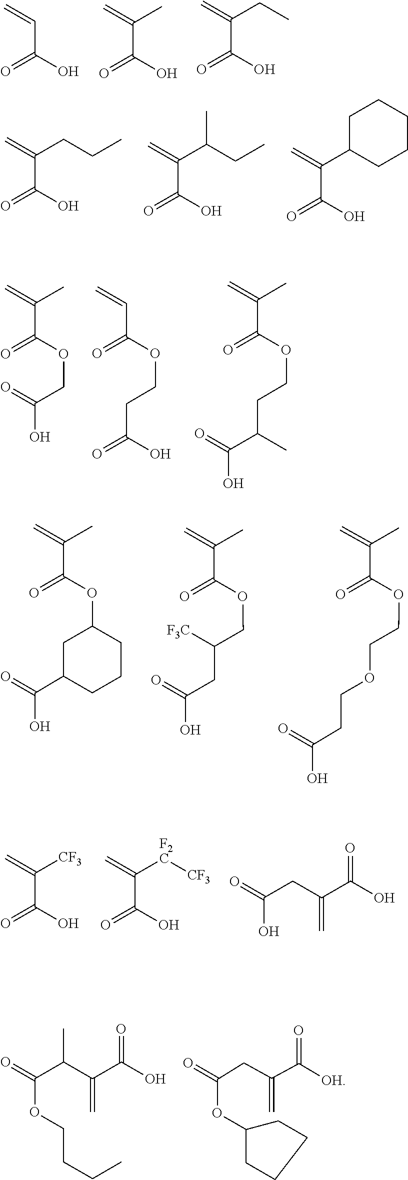

The repeating unit having a carboxylic acid group is typically present in the acid-sensitive polymer in an amount from 1 to 35 mol %, more typically from 1 to 25 mol %, still more typically from 5 to 15 mol %, based on total repeating units of the acid-sensitive polymer.

The acid-sensitive polymer may include a repeating unit comprising a lactone group. Suitable such repeating units may, for example, be derived from a monomer of formula (3):

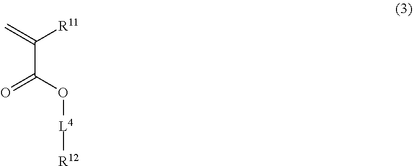

In formula (3), R¹¹ is hydrogen, fluorine, cyano, a substituted or unsubstituted C₁₋₁₀ alkyl, or a substituted or unsubstituted C₁₋₁₀ fluoroalkyl. Preferably, R¹¹ is hydrogen, fluorine, or substituted or unsubstituted C₁₋₅ alkyl, typically methyl. L⁴ may be a single bond or a divalent linking group comprising one or more of substituted or unsubstituted C₁₋₃₀ alkylene, substituted or unsubstituted C₁₋₃₀ heteroalkylene, substituted or unsubstituted C₃₋₃₀ cycloalkylene, substituted or unsubstituted C₁₋₃₀ heterocycloalkylene, substituted or unsubstituted C₆₋₃₀ arylene, substituted or unsubstituted C₇₋₃₀ arylalkylene, or substituted or unsubstituted C₁₋₃₀ heteroarylene, or substituted or unsubstituted C₃₋₃₀ heteroarylalkylene, wherein L⁴ optionally may further include one or more groups chosen, for example, from —O—, —C(O)—, —C(O)—O—, —S—, —S(O)₂—, and —N(R⁴⁴)—S(O)₂—, wherein R⁴⁴ may be hydrogen, a straight chain or branched C₁₋₂₀ alkyl, monocyclic or polycyclic C₃₋₂₀ cycloalkyl, or monocyclic or polycyclic C₃₋₂₀ heterocycloalkyl. R¹² is a lactone-containing group, for example, a monocyclic, polycyclic, or fused polycyclic C₄₋₂₀ lactone-containing group.

Non-limiting examples of monomers of formula (3) include:

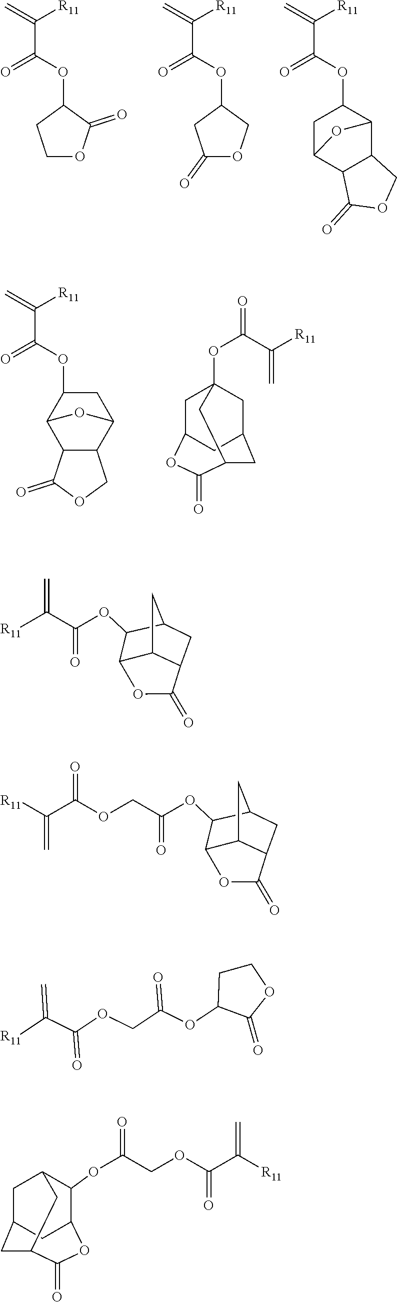

wherein R¹¹ is as described herein. Additional exemplary lactone-containing monomers include, for example, the following:

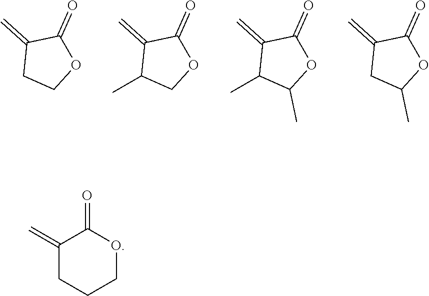

When present, the acid-sensitive polymertypically comprises a lactone repeating unit in an amount from 5 to 60 mol %, typically 20 to 55 mol %, more typically 25 to 50 mol % based on total repeating units in the acid-sensitive polymer.

The acid-sensitive polymer may include a base-soluble repeating unit having a pKa of less than or equal to 12. For example, the base-soluble repeating unit can be derived from a monomer of formula (4):

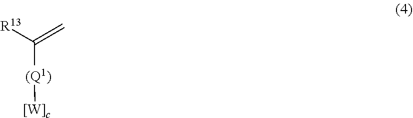

In formula (4), R¹³ may be hydrogen, fluorine, cyano, a substituted or unsubstituted C₁₋₁₀ alkyl, or a substituted or unsubstituted C₁₋₁₀ fluoroalkyl. Preferably, R¹³ is hydrogen, fluorine, or substituted or unsubstituted C₁₋₅ alkyl, typically methyl. Q¹ may be one or more of substituted or unsubstituted C₁₋₃₀ alkylene, substituted or unsubstituted C₃₋₃₀ cycloalkylene, substituted or unsubstituted C₁₋₃₀ heterocycloalkylene, substituted or unsubstituted C₆₋₃₀ arylene, substituted or unsubstituted divalent C₇₋₃₀ arylalkyl, substituted or unsubstituted C₁₋₃₀ heteroarylene, or substituted or unsubstituted divalent C₃₋₃₀ heteroarylalkyl, or —C(O)—O—. W is a base-soluble group and can be chosen, for example, from: a fluorinated alcohol such as —C(CF₃)₂OH; an amide; an imide; or —NHS(O)₂Y¹, and —C(O)NHC(O)Y¹, where Y¹ is F or C₁₋₄ perfluoroalkyl. In formula (4), c is an integer from 1 to 3.

Non-limiting examples of monomers of formula (4) include:

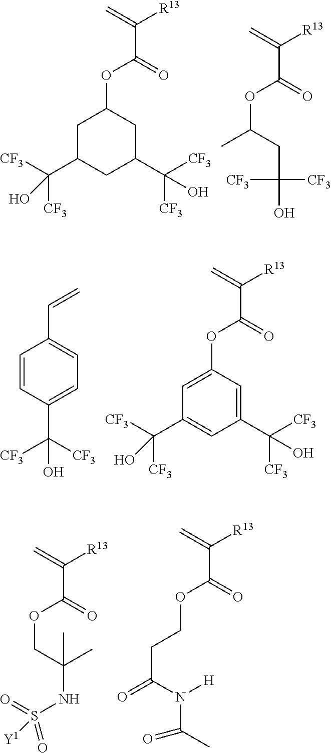

wherein R¹³ and Y¹ are as described above.

When present, the base-soluble repeating unit may be present in the acid-sensitive polymer typically in an amount from 2 to 75 mol %, typically 5 to 25 mol %, more typically 5 to 15 mol %, based on total repeating units in the acid-sensitive polymer.

The acid-sensitive polymer may optionally include one or more additional repeating units. The additional repeating units may include, for example, one or more additional units for purposes of adjusting properties of the photoresist composition, such as etch rate and solubility. Exemplary additional units may include one or more of (meth)acrylate, vinyl ether, vinyl ketone, and vinyl ester. The one or more additional repeating units if present in the acid-sensitive polymer, may be used in an amount of up to 70 mol %, typically from 3 to 50 mol %, based on total repeating units of the acid-sensitive polymer.

Suitable acid-sensitive polymers include, for example, the following:

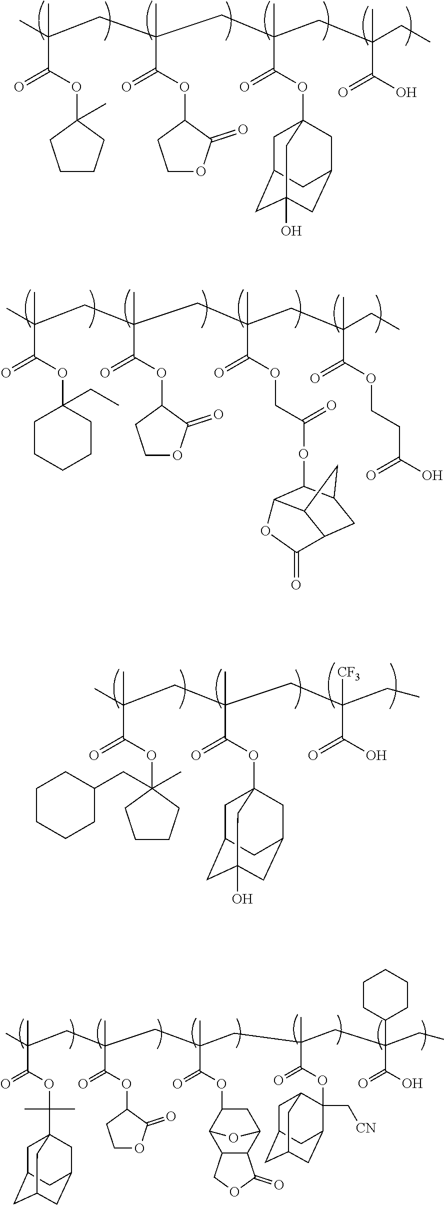

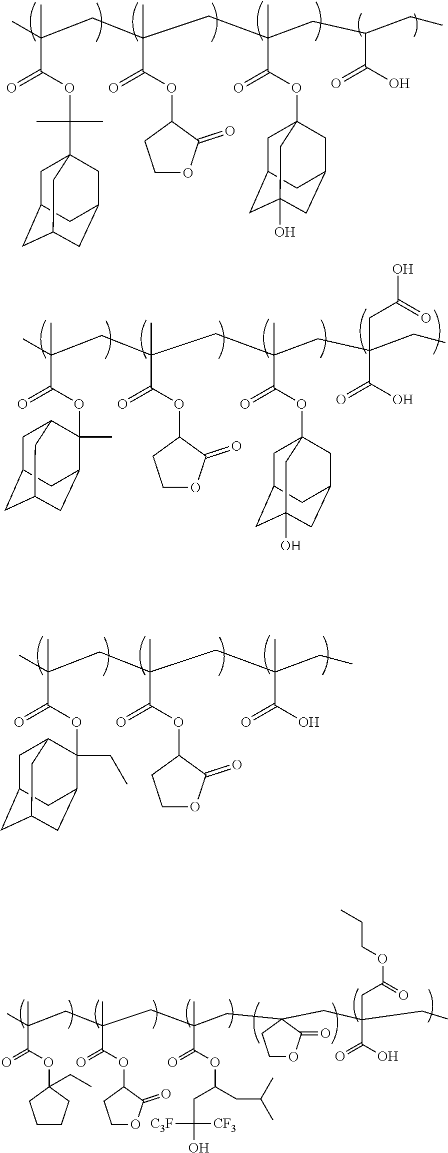

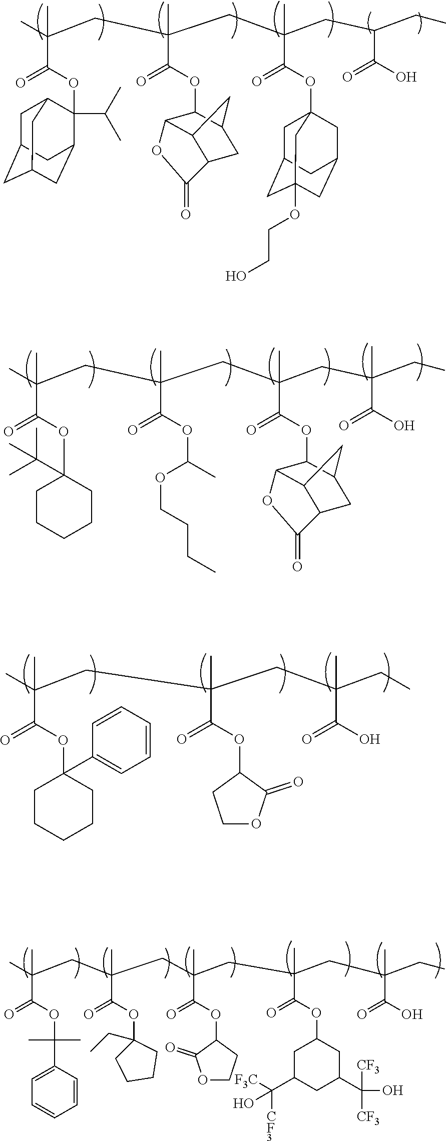

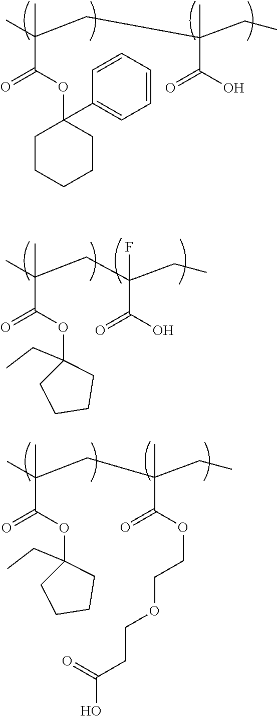

wherein the molar ratios of the units in each polymer add up to 100 mol % and may be selected, for example, in ranges such as described above.

The acid-sensitive polymer typically has a weight average molecular weight (M_{w}) of from 1000 to 50,000 Daltons (Da), more typically from 2000 to 30,000 Da, from 3000 to 20,000 Da, or from 3000 to 10,000 Da. The polydispersity index (PDI) of the acid-sensitive polymer, which is the ratio of M_{w} to number average molecular weight (Mₙ) is typically from 1.1 to 5, and more typically from 1.1 to 3. Molecular weight values as described herein are determined by gel permeation chromatography (GPC) using polystyrene standards.

In the photoresist compositions of the invention, the acid-sensitive polymer is typically present in the photoresist composition in an amount of from 0.5 to 99.9 wt %, more typically from 30 to 90 wt % or from 50 to 80 wt %, based on total solids of the photoresist composition. It will be understood that total solids includes the polymers, PAGs, and other non-solvent components.

The acid-sensitive polymer may be prepared using any suitable methods in the art, for example, free-radical polymerization, anionic polymerization, cationic polymerization, and the like. One or more monomers corresponding to the repeating units described herein may, for example, be combined, or fed separately, using suitable solvent(s) and initiator, and polymerized in a reactor. For example, the polymer and acid-sensitive polymer may be obtained by polymerization of the respective monomers under any suitable conditions, such as by heating at an effective temperature, irradiation with actinic radiation at an effective wavelength, or a combination thereof.

The compound comprising two or more enol ether groups (enol ether compound) is different from the acid-sensitive polymer and can be in non-polymeric or polymeric form. Without wishing to be bound by any particular theory, it is believed that the enol ether compound undergoes a coupling reaction between its enol ether groups and the carboxylic acid groups of the acid-sensitive polymer during a photoresist soft-bake step. This is believed to result in crosslinking of the acid-sensitive polymer, thereby increasing dissolution inhibition of the acid-sensitive polymer in an aqueous base developer solution. After exposure of the photoresist layer during post-exposure bake step, it is believed that acid generated by the photoacid generator breaks the acetal or ketal linkages of the crosslinked polymer to re-form carboxylic acid groups on the polymer in the exposed regions. This enhances dissolution of the exposed regions in the developer solution, whereas the polymer remains crosslinked with its dissolution inhibited in the unexposed regions. A higher dissolution contrast can thereby be achieved, which can result in improved LWR of the photoresist pattern.

The non-polymeric enol ether compound can, for example, be of formula (5):

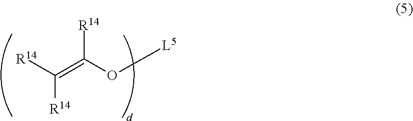

wherein: R¹⁴ independently represents —H, C₁₋₄ alkyl, or C₁₋₄ fluoroalkyl, optionally including as part of its structure one or more groups chosen from —O—, —S—, —N(R⁵)—, —C(O)—, —C(O)O—, or —C(O)N(R¹⁵)—, wherein R¹⁵ represents hydrogen or substituted or unsubstituted C₁₋₁₀ alkyl, and any two R¹⁴ groups together optionally forming a ring; L⁵ represents a linking group have a valency of d, typically C₂₋₁₀ linear alkylene, C₃₋₁₀ branched alkylene, C₃₋₁₀ cyclic alkylene, C₅₋₁₂ arylene, or a combination thereof, each of which may be substituted or unsubstituted, and optionally including as part of its structure one or more groups chosen from —O—, —S—, —N(R¹⁶)—, —C(O)—, —C(O)O—, or —C(O)N(R¹⁶)—, wherein R¹⁶ represents —H or substituted or unsubstituted C₁₋₁₀ alkyl; and d is an integer from 2 to 4.

Preferable enol ether compounds of formula (5) are compound of formula (5-1):

CH₂═CH—O—R¹⁷—O—CH═CH₂ (5-1)

wherein R¹⁷ represents C₁₋₁₀ linear alkylene, C₃₋₁₀ branched alkylene, C₃₋₁₀ cyclic alkylene, or a combination thereof, each of which may be substituted or unsubstituted.

Suitable polymeric enol ether compounds comprise repeating units formed from a free radical polymerizable monomer comprising one or more enol ether groups. The enol ether groups are typically pendant to the polymer backbone. The monomer is typically a vinyl aromatic, (meth)acrylate, or norbornyl monomer, with vinyl aromatic and (meth)acrylate being preferred. The polymeric enol ether compound can be a homopolymer or a copolymer comprising two, three, or more distinct repeating units. The polymeric enol ether compound typically has a weight average molecular weight (M_{W}) of from 200 to 100,000 Da and a PDI of from 1.1 to 5.

Suitable enol ether compounds include, for example, the following:

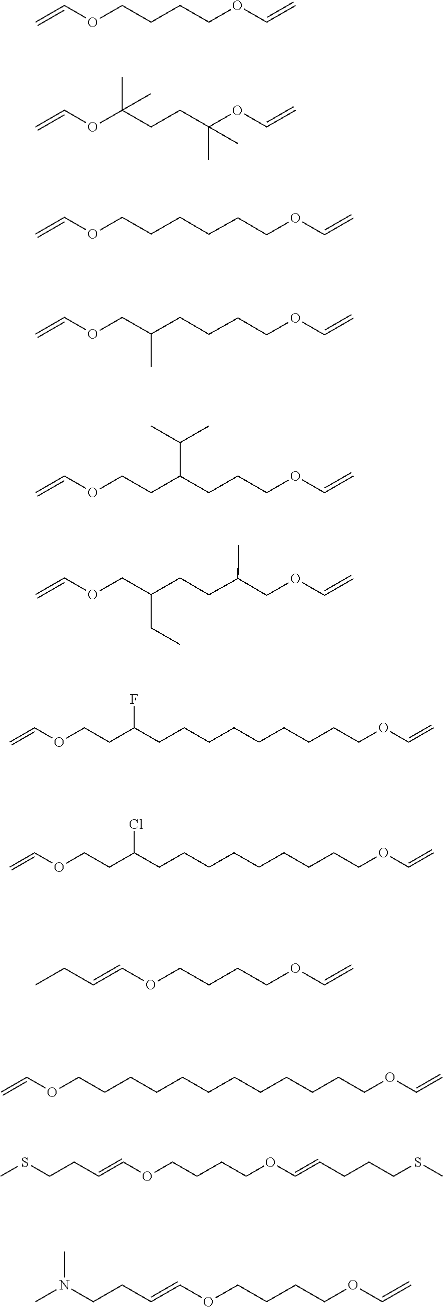

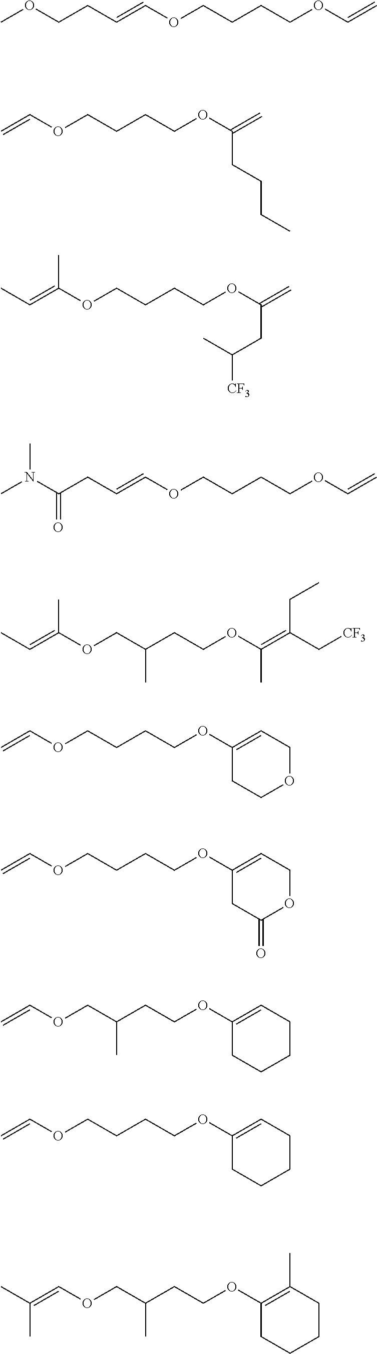

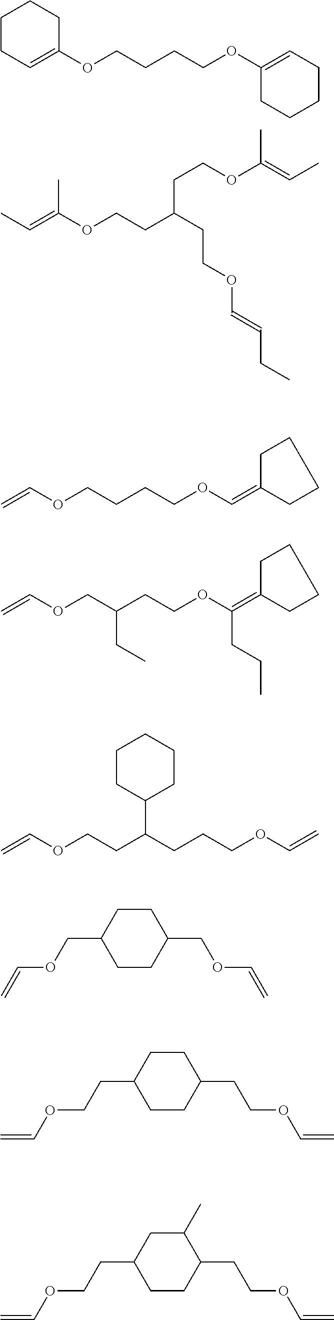

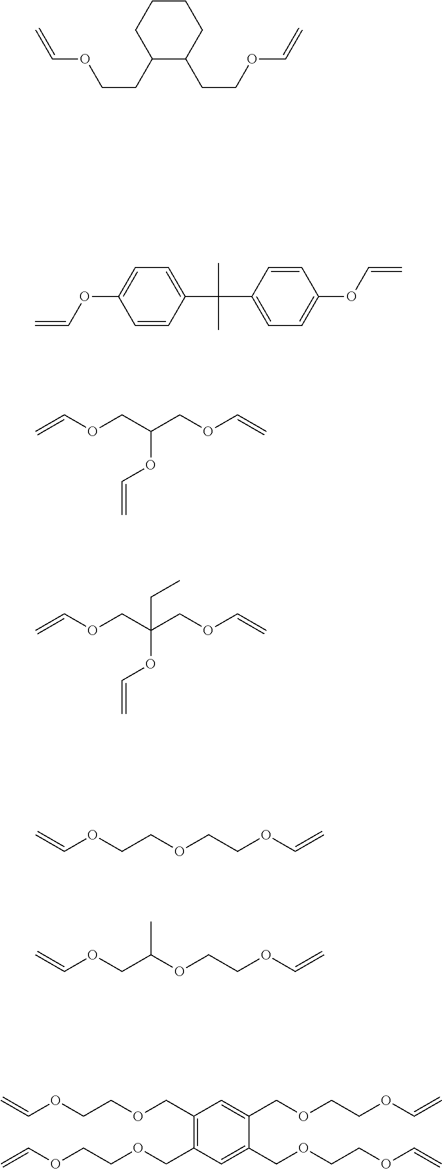

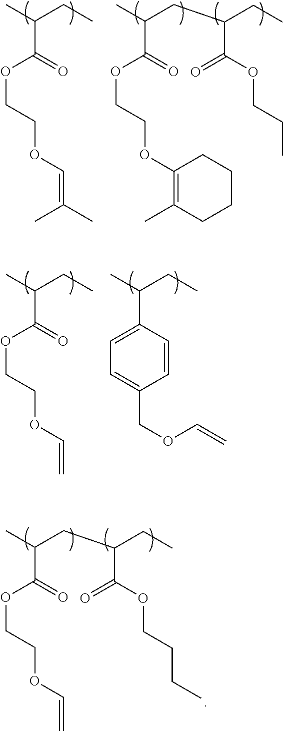

The enol ether compound is typically present in the photoresist composition in an amount of from 0.01 to 60 wt %, typically from 1 to 30 wt %, more typically from 3 to 15 wt %, based on total solids of the photoresist composition. Suitable enol ether compounds are commercially available and/or can readily made by persons skilled in the art.

The photoresist composition further comprises a photoacid generator (PAG). The PAG is typically of non-polymeric form, but may be in polymeric form, for example, present in a polymerized repeating unit of the acid-sensitive polymer or as part of a different polymer. Suitable PAGs can generate an acid that, during post-exposure bake, causes cleavage of acid-decomposable groups present on a polymer of the photoresist composition. Suitable PAG compounds are known in the art of chemically amplified photoresists and may be ionic or nonionic. Suitable PAG compounds include, for example: onium salts, for example, triphenylsulfonium trifluoromethanesulfonate, (p-tert-butoxyphenyl)diphenylsulfonium trifluoromethanesulfonate, tris(p-tert-butoxyphenyl)sulfonium trifluoromethanesulfonate, triphenylsulfonium p-toluenesulfonate; di-t-butyphenyliodonium perfluorobutanesulfonate, and di-t-butyphenyliodonium camphorsulfonate. Non-ionic sulfonates and sulfonyl compounds are also known to function as photoacid generators, e.g., nitrobenzyl derivatives, for example, 2-nitrobenzyl-p-toluenesulfonate, 2,6-dinitrobenzyl-p-toluenesulfonate, and 2,4-dinitrobenzyl-p-toluenesulfonate; sulfonic acid esters, for example, 1,2,3-tris(methanesulfonyloxy)benzene, 1,2,3-tris(trifluoromethanesulfonyloxy)benzene, and 1,2,3-tris(p-toluenesulfonyloxy)benzene; diazomethane derivatives, for example, bis(benzenesulfonyl)diazomethane, bis(p-toluenesulfonyl)diazomethane; glyoxime derivatives, for example, bis-O-(p-toluenesulfonyl)-α-dimethylglyoxime, and bis-O-(n-butanesulfonyl)-α-dimethylglyoxime; sulfonic acid ester derivatives of an N-hydroxyimide compound, for example, N-hydroxysuccinimide methanesulfonic acid ester, N-hydroxysuccinimide trifluoromethanesulfonic acid ester; and halogen-containing triazine compounds, for example, 2-(4-methoxyphenyl)-4,6-bis(trichloromethyl)-1,3,5-triazine, and 2-(4-methoxynaphthyl)-4,6-bis(trichloromethyl)-1,3,5-triazine. Suitable photoacid generators are further described in U.S. Pat. No. 8,431,325 to Hashimoto et al. in column 37, lines 11-47 and columns 41-91. Other suitable sulfonate PAGs include sulfonated esters and sulfonyloxy ketones, nitrobenzyl esters, s-triazine derivatives, benzoin tosylate, t-butylphenyl α-(p-toluenesulfonyloxy)-acetate, and t-butyl α-(p-toluenesulfonyloxy)-acetate; as described in U.S. Pat. Nos. 4,189,323 and 8,431,325.

Particularly suitable PAGs are of the formula G⁺A⁻, wherein G⁺ is an organic cation and A⁻ is an organic anion. Organic cations include, for example, iodonium cations substituted with two alkyl groups, aryl groups, or a combination of alkyl and aryl groups; and sulfonium cations substituted with three alkyl groups, aryl groups, or a combination of alkyl and aryl groups. In some embodiments, G⁺ is an iodonium cation substituted with two alkyl groups, aryl groups, or a combination of alkyl and aryl groups; or a sulfonium cation substituted with three alkyl groups, aryl groups, or a combination of alkyl and aryl groups. In some embodiments, G⁺ may be one or more of a substituted sulfonium cation having the formula (6A) or an iodonium cation having the formula (6B):

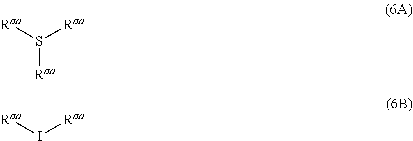

wherein, each R^{aa} is independently a C₁₋₂₀ alkyl group, a C₁₋₂₀ fluoroalkyl group, a C₃₋₂₀ cycloalkyl group, a C₃₋₂₀ fluorocycloalkyl group, a C₂₋₂₀ alkenyl group, a C₂₋₂₀ fluoroalkenyl group, a C₆₋₃₀ aryl group, a C₆₋₃₀ fluoroaryl group, C₆₋₃₀ iodoaryl group, a C₄₋₃₀ heteroaryl group, a C₇₋₂₀ arylalkyl group, a C₇₋₂₀ fluoroarylalkyl group, a C₅₋₃₀ heteroarylalkyl group, or a C₅₋₃₀ fluoroheteroarylalkyl group, each of which is substituted or unsubstituted, wherein each R^{aa} is either separate or connected to another group R^{aa} via a single bond or a divalent linking group to form a ring. Each R^{aa} optionally may include as part of its structure one or more groups selected from —O—, —C(O)—, —C(O)—O—, —C₁₋₁₂ hydrocarbylene-, —O—(C₁₋₁₂ hydrocarbylene)-, —C(O)—O—(C₁₋₁₂ hydrocarbylene)-, and —C(O)—O—(C₁₋₁₂ hydrocarbylene)-O—. Each R^{aa} independently may optionally comprise an acid-decomposable group chosen, for example, from tertiary alkyl ester groups, secondary or tertiary aryl ester groups, secondary or tertiary ester groups having a combination of alkyl and aryl groups, tertiary alkoxy groups, acetal groups, or ketal groups. Suitable divalent linking groups for connection of R^{aa} groups include, for example, —O—, —S—, —Te—, —Se—, —C(O)—, —C(S)—, —C(Te)—, or —C(Se)—, substituted or unsubstituted C₁₋₅ alkylene, and combinations thereof.

Exemplary sulfonium cations of formula (6A) include the following:

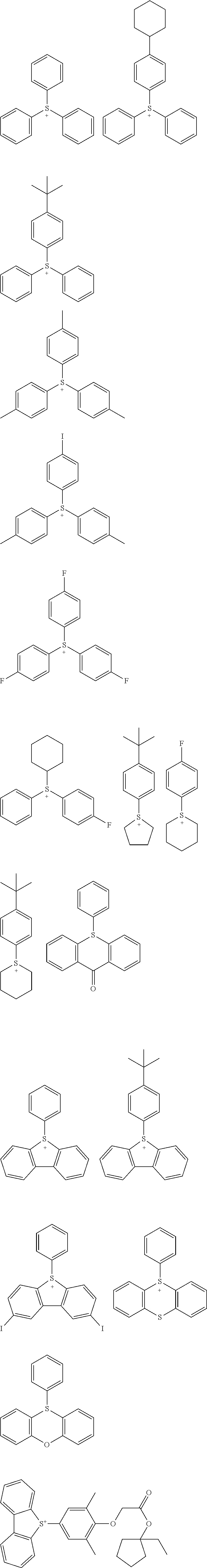

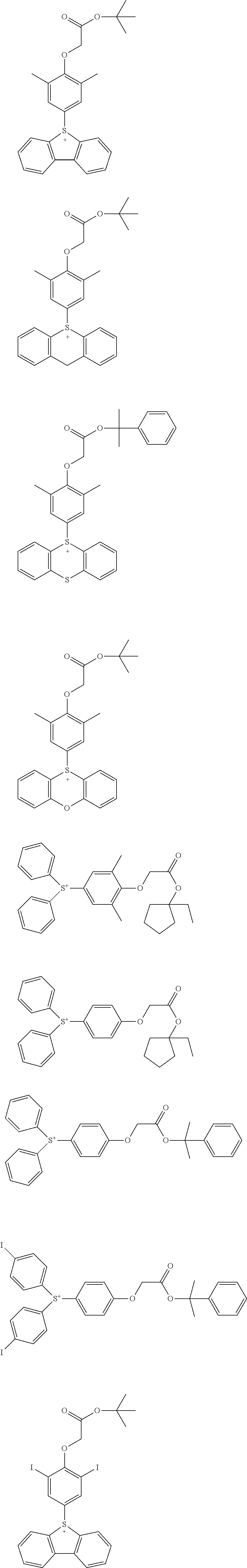

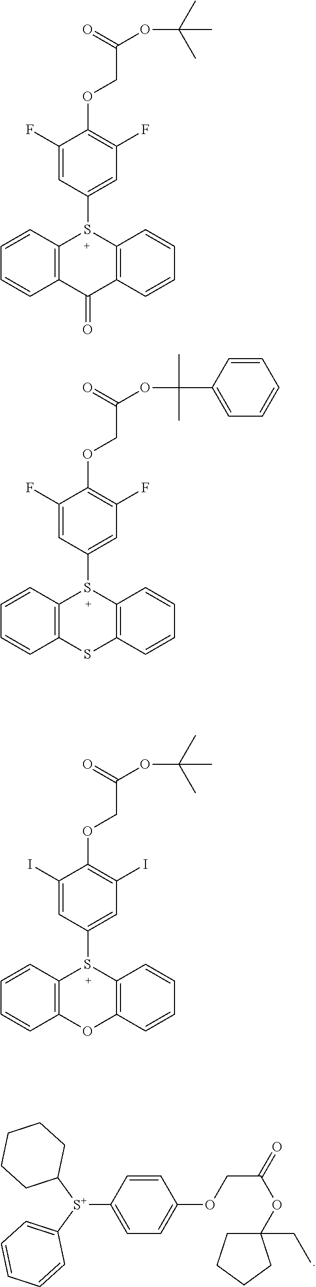

Exemplary iodonium cations of formula (6B) include the following:

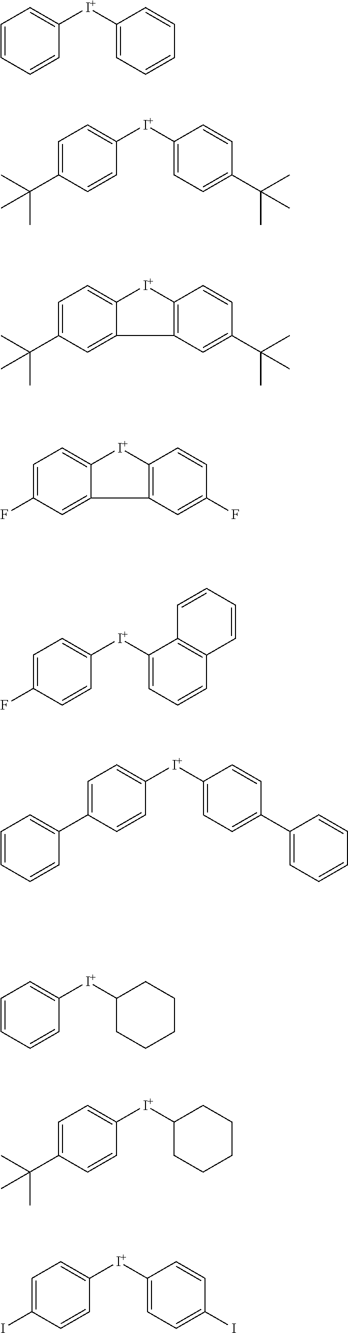

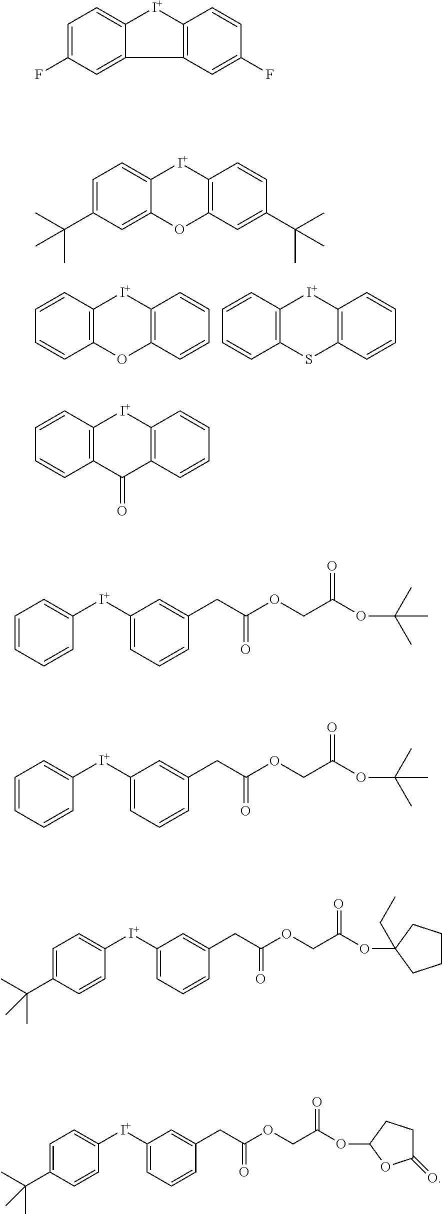

PAGs that are onium salts typically comprise an anion having a sulfonate group or a non-sulfonate type group, such as a sulfonamidate group, a sulfonimidate group, a methide group, or a borate group. Exemplary suitable anions having a sulfonate group include the following:

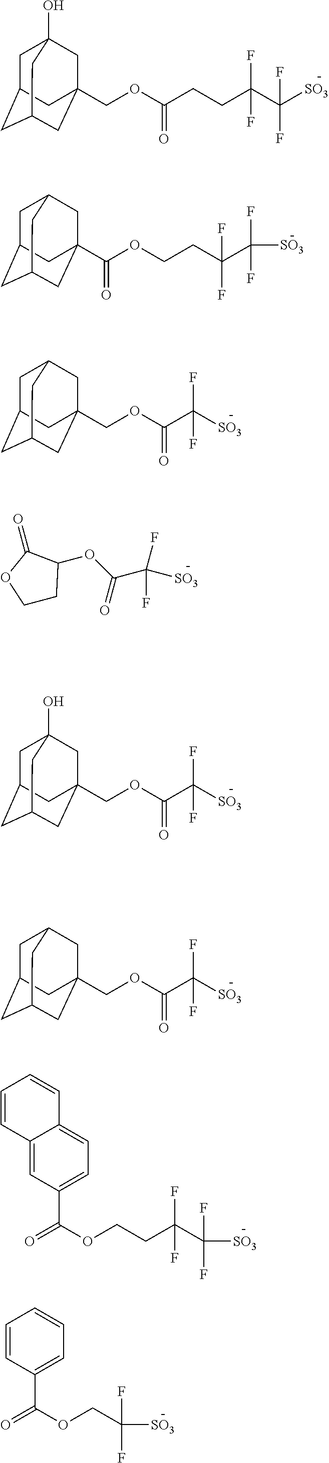

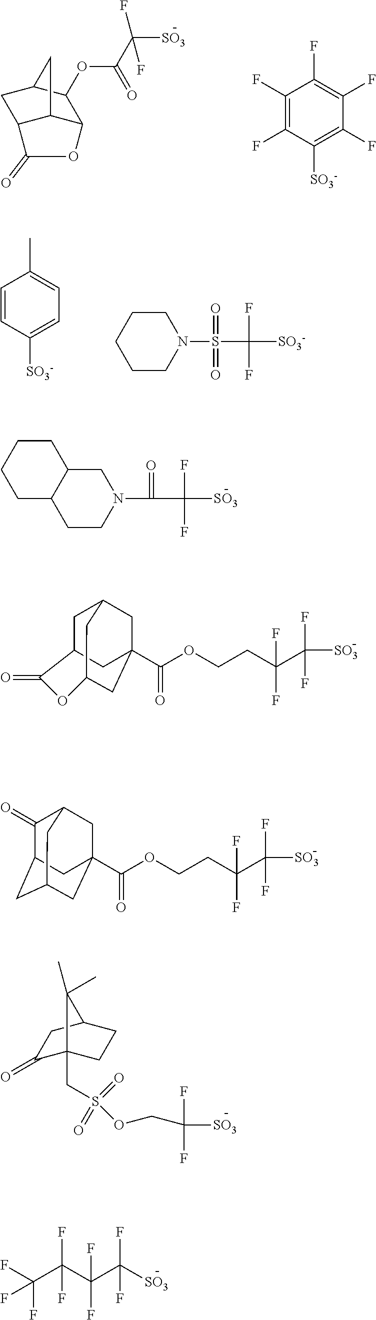

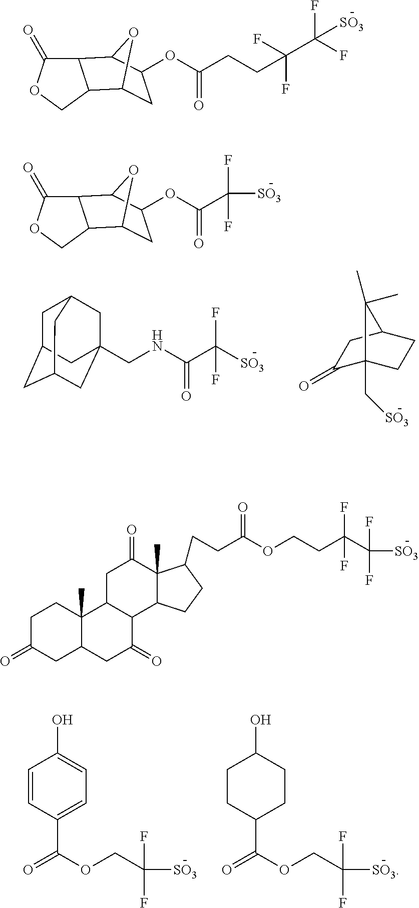

Exemplary suitable non-sulfonated anions include the following:

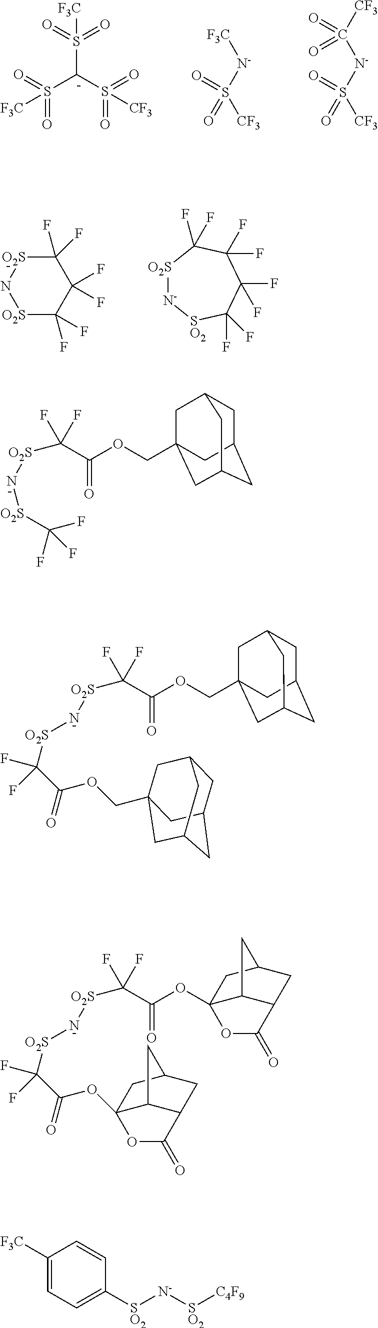

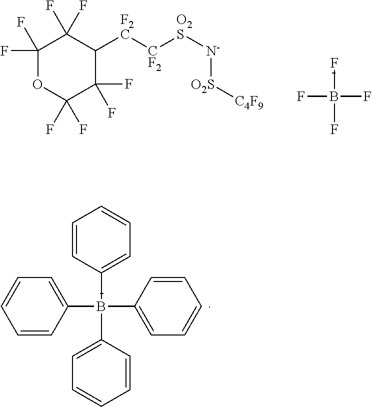

The photoresist composition may optionally comprise a plurality of PAGs. Typically, the photoacid generator is present in the photoresist composition in an amount from 1 to 65 wt %, more typically from 5 to 55 wt %, and still more typically from 8 to 30 wt %, based on total solids of the photoresist composition.

The photoresist composition further includes a material that comprises one or more base-labile groups (a “base-labile material”). As referred to herein, base-labile groups are functional groups that can undergo cleavage reaction to provide polar groups such as hydroxyl, carboxylic acid, sulfonic acid, and the like, in the presence of an aqueous alkaline developer after exposure and post-exposure baking steps. The base-labile group will not react significantly (e.g., will not undergo a bond-breaking reaction) prior to a development step of the photoresist composition that comprises the base-labile group. Thus, for instance, a base-labile group will be substantially inert during pre-exposure soft-bake, exposure, and post-exposure bake steps. By “substantially inert” it is meant that 5%, preferably 1%, of the base-labile groups (or moieties) will decompose, cleave, or react during the pre-exposure soft-bake, exposure, and post-exposure bake steps. The base-labile group is reactive under typical photoresist development conditions using, for example, an aqueous alkaline photoresist developer such as a 0.26 normal (N) aqueous solution of tetramethylammonium hydroxide (TMAH). For example, a 0.26 N aqueous solution of TMAH may be used for single puddle development or dynamic development, e.g., where the 0.26 N TMAH developer is dispensed onto an imaged photoresist layer for a suitable time such as 10 to 120 seconds (s). An exemplary base-labile group is an ester group, typically a fluorinated ester group. Preferably, the base-labile material is substantially not miscible with and has a lower surface energy than the first and second polymers, and other solid components of the photoresist composition. When coated on a substrate, the base-labile material can thereby segregate from other solid components of the photoresist composition to a top surface of the formed photoresist layer.

In some aspects, the base-labile material is a polymeric material, also referred to herein as a base-labile polymer, which may include one or more repeating units comprising one or more base-labile groups. For example, the base-labile polymer may comprise a repeating unit comprising 2 or more base-labile groups that are the same or different. A preferred base-labile polymer comprises at least one repeating unit comprising 2 or more base-labile groups, for example a repeating unit comprising 2 or 3 base-labile groups.

The base-labile polymer may be a polymer comprising a repeating unit derived from a monomer of formula (7-1)

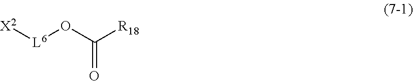

wherein X² is a polymerizable group selected from vinyl and acrylic, L⁶ is a divalent linking group comprising one or more of substituted or unsubstituted linear or branched C₁₋₂₀ alkylene, substituted or unsubstituted C₃₋₂₀ cycloalkylene, —C(O)—, or —C(O)O—; and R¹⁸ is a substituted or unsubstituted C₁₋₂₀ fluoroalkyl group provided that the carbon atom bonded to the carbonyl (C═O) in formula (7-1) is substituted with at least one fluorine atom.

Exemplary monomers of formula (7-1) include the following:

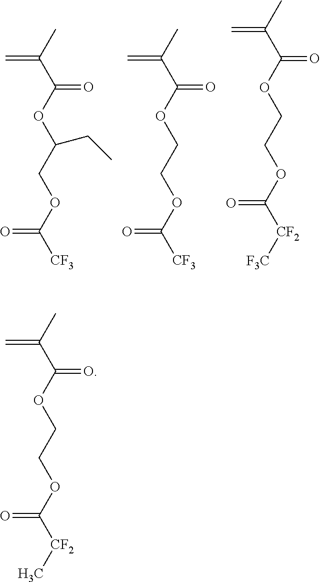 [SMILES: C=C(C)C(=O)OC(CC)COC(=O)C(F)(F)F ; C=C(C)C(=O)OCCOC(=O)C(F)(F)F ; C=C(C)C(=O)OCCOC(=O)C(F)(F)C(F)(F)F ; C=C(C)C(=O)OCCOC(=O)C(C)(F)F]

The base-labile polymer may include a repeating unit including two or more base-labile groups. For example, the base-labile polymer can include a repeating unit derived from a monomer of formula (7-2)

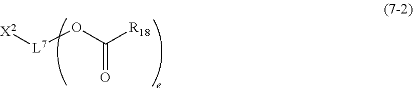

wherein X² and R¹⁸ are as defined in formula (7-1); L⁷ is a polyvalent linking group comprising one or more of substituted or unsubstituted straight chain or branched C₁₋₂₀ alkylene, substituted or unsubstituted C₃₋₂₀ cycloalkylene, —C(O)—, or —C(O)O—; and e is an integer of 2 or more, for example, 2 or 3.

Exemplary monomers of formula (7-2) include the following:

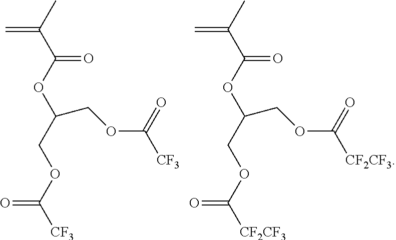

The base-labile polymer may include a repeating unit including one or more base-labile groups. For example, the base-labile polymer can include a repeating unit derived from a monomer of formula (7-3):

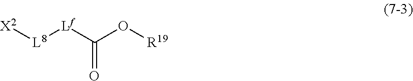

wherein X² is as defined in formula (7-1); L⁸ is a divalent linking group comprising one or more of substituted or unsubstituted straight chain or branched C₁₋₂₀ alkylene, substituted or unsubstituted C₃₋₂₀ cycloalkylene, —C(O)—, or —C(O)O—; Lf is a substituted or unsubstituted C₁₋₂₀ fluoroalkylene group wherein the carbon atom bonded to the carbonyl (C═O) in formula (7-3) is substituted with at least one fluorine atom; and R¹⁹ is substituted or unsubstituted straight chain or branched C₁₋₂₀ alkyl, or substituted or unsubstituted C₃₋₂₀ cycloalkyl.

Exemplary monomers of formula (7-3) include the following:

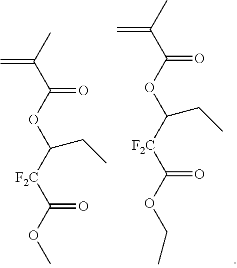 [SMILES: C=C(C)C(=O)OC(CC)C(F)(F)C(=O)OC ; C=C(C)C(=O)OC(CC)C(F)(F)C(=O)OCC]

In a further preferred aspect of the invention, a base-labile polymer may comprise one or more base-labile groups and one or more acid-labile groups, such as one or more acid-labile ester moieties (e.g. t-butyl ester) or acid-labile acetal groups. For example, the base-labile polymer may comprise a repeating unit including a base-labile group and an acid-labile group, i.e., wherein both a base-labile group and an acid-labile group are present on the same repeating unit. In another example, the base-labile polymer may comprise a first repeating unit comprising a base-labile group and a second repeating unit comprising an acid-labile group. Preferred photoresists of the invention can exhibit reduced defects associated with a resist relief image formed from the photoresist composition.

The base-labile polymer may be prepared using any suitable methods in the art, including those described herein for the first and second polymers. For example, the base-labile polymer may be obtained by polymerization of the respective monomers under any suitable conditions, such as by heating at an effective temperature, irradiation with actinic radiation at an effective wavelength, or a combination thereof. Additionally, or alternatively, one or more base-labile groups may be grafted onto the backbone of a polymer using suitable methods.

In some aspects, the base-labile material is a single molecule comprising one more base-labile ester groups, preferably one or more fluorinated ester groups. They base-labile materials that are single molecules may have a MW in the range of from 50 to 1,500 Da. Exemplary base-labile materials include the following:

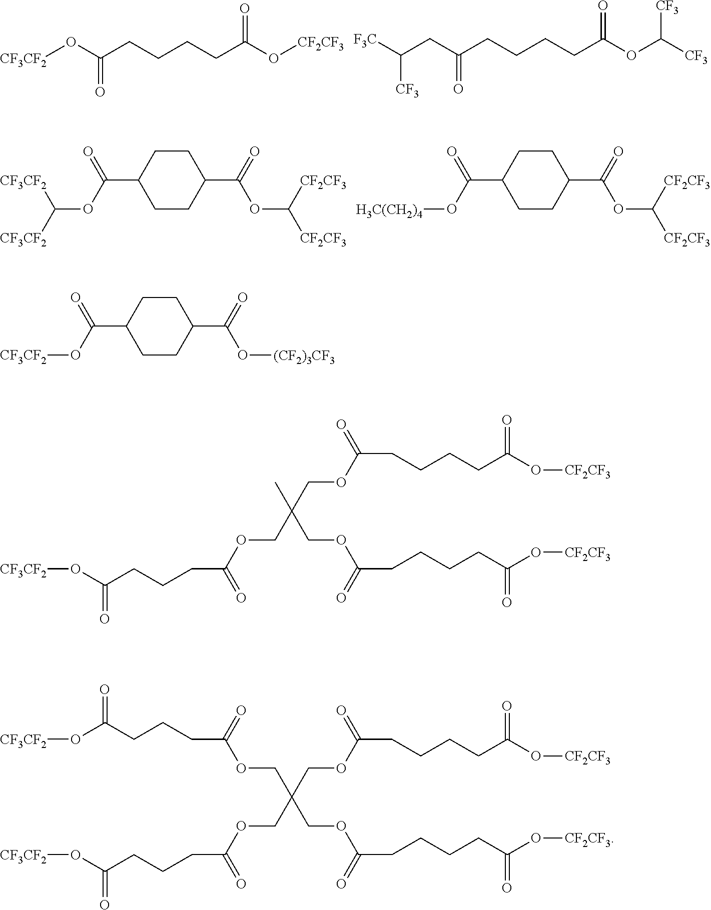

The photoresist compositions may further include one or more polymers in addition to and different from the acid-sensitive polymer described above. For example, the photoresist compositions may include an additional polymer as described above but different in composition, or a polymer that is similar to those described above but does not include a requisite repeating unit. Additionally, or alternatively, the one or more additional polymers may include those well known in the photoresist art, for example, those chosen from polyacrylates, polyvinylethers, polyesters, polynorbornenes, polyacetals, polyethylene glycols, polyamides, polyacrylamides, polyphenols, novolacs, styrenic polymers, polyvinyl alcohols, or combinations thereof.

The photoresist compositions further include a solvent for dissolving the components of the composition and facilitating its coating on a substrate. Preferably, the solvent is an organic solvent conventionally used in the manufacture of electronic devices. Suitable solvents include, for example: aliphatic hydrocarbons such as hexane and heptane; aromatic hydrocarbons such as toluene and xylene; halogenated hydrocarbons such as dichloromethane, 1,2-dichloroethane, and 1-chlorohexane; alcohols such as methanol, ethanol, 1-propanol, iso-propanol, tert-butanol, 2-methyl-2-butanol, and 4-methyl-2-pentanol; propylene glycol monomethyl ether (PGME), ethers such as diethyl ether, tetrahydrofuran, 1,4-dioxane, and anisole; ketones such as acetone, methyl ethyl ketone, methyl iso-butyl ketone, 2-heptanone, and cyclohexanone (CHO); esters such as ethyl acetate, n-butyl acetate, propylene glycol monomethyl ether acetate (PGMEA), ethyl lactate (EL), hydroxyisobutyrate methyl ester (HBM), and ethyl acetoacetate; lactones such as gamma-butyrolactone (GBL) and epsilon-caprolactone; lactams such as N-methyl pyrrolidone; nitriles such as acetonitrile and propionitrile; cyclic or non-cyclic carbonate esters such as propylene carbonate, dimethyl carbonate, ethylene carbonate, propylene carbonate, diphenyl carbonate, and propylene carbonate; polar aprotic solvents such as dimethyl sulfoxide and dimethyl formamide; water; and combinations thereof. Of these, preferred solvents are PGME, PGMEA, EL, GBL, HBM, CHO, and combinations thereof. The total solvent content (i.e., cumulative solvent content for all solvents) in the photoresist compositions is typically from 40 to 99 wt %, for example, from 70 to 99 wt %, or from 85 to 99 wt %, based on total solids of the photoresist composition. The desired solvent content will depend, for example, on the desired thickness of the coated photoresist layer and coating conditions.

The photoresist composition may further include one or more additional, optional additives. Such optional additives may include, for example, actinic and contrast dyes, anti-striation agents, plasticizers, speed enhancers, sensitizers, photo-decomposable quenchers (also known as photo-decomposable bases), basic quenchers, surfactants, and the like, or combinations thereof. If present, the optional additives are typically present in the photoresist compositions in an amount of from 0.01 to 10 wt %, based on total solids of the photoresist composition.

Photo-decomposable quenchers generate a weak acid upon irradiation. The acid generated from a photo-decomposable quencher is not strong enough to react rapidly with acid-decomposable groups that are present in the resist matrix. Exemplary photo-decomposable quenchers include, for example, photo-decomposable cations, and preferably those also useful for preparing strong acid generator compounds but paired with an anion of a weak acid (pKa>1) such as, for example, a C1-20 carboxylic acid or C1-20 sulfonic acid. Exemplary carboxylic acids include formic acid, acetic acid, propionic acid, tartaric acid, succinic acid, cyclohexanecarboxylic acid, benzoic acid, salicylic acid, and the like. Exemplary carboxylic acids include p-toluene sulfonic acid, camphor sulfonic acid and the like. In a preferred embodiment, the photo-decomposable quencher is a photo-decomposable organic zwitterion compound such as diphenyliodonium-2-carboxylate.

Exemplary basic quenchers include, for example: linear aliphatic amines such as tributylamine, trioctylamine, triisopropanolamine, tetrakis(2-hydroxypropyl)ethylenediamine:n-tert-butyldiethanolamine, tris(2-acetoxy-ethyl) amine, 2,2′,2″,2′″-(ethane-1,2-diylbis(azanetriyl))tetraethanol, 2-(dibutylamino)ethanol, and 2,2′,2″-nitrilotriethanol; cyclic aliphatic amines such as 1-(tert-butoxycarbonyl)-4-hydroxypiperidine, tert-butyl 1-pyrrolidinecarboxylate, tert-butyl 2-ethyl-1H-imidazole-1-carboxylate, di-tert-butyl piperazine-1,4-dicarboxylate, and N-(2-acetoxy-ethyl)morpholine; aromatic amines such as pyridine, di-tert-butyl pyridine, and pyridinium; linear and cyclic amides and derivatives thereof such as N,N-bis(2-hydroxyethyl)pivalamide, N,N-diethylacetamide, N1,N1,N3,N3-tetrabutylmalonamide, 1-methylazepan-2-one, 1-allylazepan-2-one, and tert-butyl 1,3-dihydroxy-2-(hydroxymethyl)propan-2-ylcarbamate; ammonium salts such as quaternary ammonium salts of sulfonates, sulfamates, carboxylates, and phosphonates; imines such as primary and secondary aldimines and ketimines; diazines such as optionally substituted pyrazine, piperazine, and phenazine; diazoles such as optionally substituted pyrazole, thiadiazole, and imidazole; and optionally substituted pyrrolidones such as 2-pyrrolidone and cyclohexyl pyrrolidine.

Exemplary surfactants include fluorinated and non-fluorinated surfactants and can be ionic or non-ionic, with non-ionic surfactants being preferable. Exemplary fluorinated non-ionic surfactants include perfluoro C4 surfactants such as FC-4430 and FC-4432 surfactants, available from 3M Corporation; and fluorodiols such as POLYFOX PF-636, PF-6320, PF-656, and PF-6520 fluorosurfactants from Omnova. In an aspect, the photoresist composition may further include a surfactant polymer including a fluorine-containing repeating unit.

Patterning methods using the photoresist compositions of the invention will now be described. Suitable substrates on which the photoresist compositions can be coated include electronic device substrates. A wide variety of electronic device substrates may be used in the present invention, such as: semiconductor wafers; polycrystalline silicon substrates; packaging substrates such as multichip modules; flat panel display substrates; substrates for light emitting diodes (LEDs) including organic light emitting diodes (OLEDs); and the like, with semiconductor wafers being typical. Such substrates are typically composed of one or more of silicon, polysilicon, silicon oxide, silicon nitride, silicon oxynitride, silicon germanium, gallium arsenide, aluminum, sapphire, tungsten, titanium, titanium-tungsten, nickel, copper, and gold. Suitable substrates may be in the form of wafers such as those used in the manufacture of integrated circuits, optical sensors, flat panel displays, integrated optical circuits, and LEDs. Such substrates may be any suitable size. Typical wafer substrate diameters are 200 to 300 millimeters (mm), although wafers having smaller and larger diameters may be suitably employed according to the present invention. The substrates may include one or more layers or structures which may optionally include active or operable portions of devices being formed.

Typically, one or more lithographic layers such as a hardmask layer, for example, a spin-on-carbon (SOC), amorphous carbon, or metal hardmask layer, a CVD layer such as a silicon nitride (SiN), a silicon oxide (SiO), or silicon oxynitride (SiON) layer, an organic or inorganic underlayer such as a bottom antireflective coating (BARC) layer, or combinations thereof, are provided on an upper surface of the substrate prior to coating a photoresist composition of the present invention. Such layers, together with an overcoated photoresist layer, form a lithographic material stack.

Optionally, a layer of an adhesion promoter may be applied to the substrate surface prior to coating the photoresist compositions. If an adhesion promoter is desired, any suitable adhesion promoter for polymer films may be used, such as silanes, typically organosilanes such as trimethoxyvinylsilane, triethoxyvinylsilane, hexamethyldisilazane, or an aminosilane coupler such as gamma-aminopropyltriethoxysilane. Particularly suitable adhesion promoters include those sold under the AP 3000, AP 8000, and AP 9000S designations, available from DuPont Electronics & Imaging (Marlborough, Mass.).

The photoresist composition may be coated on the substrate by any suitable method, including spin coating, spray coating, dip coating, doctor blading, or the like. For example, applying the layer of photoresist may be accomplished by spin coating the photoresist in solvent using a coating track, in which the photoresist is dispensed on a spinning wafer. During dispensing, the wafer is typically spun at a speed of up to 4,000 rotations per minute (rpm), for example, from 200 to 3,000 rpm, for example, 1,000 to 2,500 rpm, for a period of from 15 to 120 seconds to obtain a layer of the photoresist composition on the substrate. It will be appreciated by those skilled in the art that the thickness of the coated layer may be adjusted by changing the spin speed and/or the solids content of the composition. A photoresist layer formed from the compositions of the invention typically has a dried layer thickness of from 10 to 3000 nanometers (nm), more typically from 15 to 500 nm, from 20 to 200 nm, or from 50 to 150 nm.

The photoresist composition is typically next soft-baked to minimize the solvent content in the layer, thereby forming a tack-free coating and improving adhesion of the layer to the substrate. The soft-bake is also believed to cause reaction between the enol ether-group containing compound and the carboxylic acid groups of the acid-sensitive polymer, resulting in crosslinking of the acid-sensitive polymer. The soft-bake is performed, for example, on a hotplate or in an oven, with a hotplate being typical. The soft-bake temperature and time will depend, for example, on the particular photoresist composition and thickness. The soft-bake temperature is typically from 90 to 170° C., for example, from 110 to 150° C. The soft-bake time is typically from 10 seconds to 20 minutes, for example, from 1 minute to 10 minutes, or from 1 minute to 5 minutes. The soft-bake temperature and time can be readily determined by one of ordinary skill in the art based on the components of the composition.

The photoresist layer is next pattern-wise exposed to activating radiation to create a difference in solubility between exposed and unexposed regions. It may be desirable to include a delay between soft-bake and exposure. Suitable delay times include, for example from 5 seconds to 30 minutes or from 1 to 5 minutes. Reference herein to exposing a photoresist composition to radiation that is activating for the composition indicates that the radiation is capable of forming a latent image in the photoresist composition. The exposure is typically conducted through a patterned photomask that has optically transparent and optically opaque regions corresponding to regions of the resist layer to be exposed and unexposed, respectively. Such exposure may, alternatively, be conducted without a photomask in a direct writing method, typically used for e-beam lithography. The activating radiation typically has a wavelength of sub-400 nm, sub-300 nm or sub-200 nm, such as 248 nm (KrF), 193 nm (ArF), and 13.5 nm (extreme ultraviolet, EUV) wavelengths or e-beam lithography. The methods find use in immersion or dry (non-immersion) lithography techniques. The exposure energy is typically from 1 to 200 millijoules per square centimeter (mJ/cm²), preferably 10 to 100 mJ/cm² and more preferably 20 to 50 mJ/cm², dependent upon the exposure tool and components of the photoresist composition. In a preferred aspect, the activating radiation is 193 nm (ArF), with 193 nm immersion lithography being particularly preferred.

Following exposure of the photoresist layer, a post-exposure bake (PEB) of the exposed photoresist layer is performed. It may be desirable to include a pest-exposure delay (PED) between exposure and PEB. Suitable PED times include, for example from 5 seconds to 30 minutes or from 1 to 5 minutes. The PEB can be conducted, for example, on a hotplate or in an oven, with a hotplate being typical. Conditions for the PEB will depend, for example, on the particular photoresist composition and layer thickness. The PEB is typically conducted at a temperature of from 80 to 150° C., and a time of from 30 to 120 seconds. A latent image defined by the polarity-switched (exposed regions) and unswitched regions (unexposed regions) is formed in the photoresist. It is believed that during PEB, photo-generated acid breaks the ketal linkages of the crosslinked polymer to re-form carboxylic acid groups on the polymer in the exposed regions.

The exposed photoresist layer is next developed with a suitable developer to selectively remove those regions of the layer that are soluble in the developer while the remaining insoluble regions form the resulting photoresist pattern relief image. In the case of a positive-tone development (PTD) process, the exposed regions of the photoresist layer are removed during development and unexposed regions remain. Conversely, in a negative-tone development (NTD) process, the exposed regions of the photoresist layer remain, and unexposed regions are removed during development. Application of the developer may be accomplished by any suitable method such as described above with respect to application of the photoresist composition, with spin coating being typical. The development time is for a period effective to remove the soluble regions of the photoresist, with a time of from 5 to 60 seconds being typical. Development is typically conducted at room temperature.

Suitable developers for a PTD process include aqueous base developers, for example, quaternary ammonium hydroxide solutions such as tetramethylammonium hydroxide (TMAH), preferably 0.26 normal (N) TMAH, tetraethylammonium hydroxide, tetrabutylammonium hydroxide, sodium hydroxide, potassium hydroxide, sodium carbonate, potassium carbonate, and the like. Suitable developers for an NTD process are organic solvent-based, meaning the cumulative content of organic solvents in the developer is 50 wt % or more, typically 95 wt % or more, 95 wt % or more, 98 wt % or more, or 100 wt %, based on total weight of the developer. Suitable organic solvents for the NTD developer include, for example, those chosen from ketones, esters, ethers, hydrocarbons, and mixtures thereof. The developer is typically 2-heptanone or n-butyl acetate.

A coated substrate may be formed from the photoresist compositions of the invention. Such a coated substrate includes: (a) a substrate having one or more layers to be patterned on a surface thereof, and (b) a layer of the photoresist composition over the one or more layers to be patterned.

The photoresist pattern may be used, for example, as an etch mask, thereby allowing the pattern to be transferred to one or more sequentially underlying layers by known etching techniques, typically by dry-etching such as reactive ion etching. The photoresist pattern may, for example, be used for pattern transfer to an underlying hardmask layer which, in turn, is used as an etch mask for pattern transfer to one or more layers below the hardmask layer. If the photoresist pattern is not consumed during pattern transfer, it may be removed from the substrate by known techniques, for example, oxygen plasma ashing. The photoresist compositions may, when used in one or more such patterning processes, be used to fabricate semiconductor devices such as memory devices, processor chips (CPUs), graphics chips, optoelectronic chips, LEDs, OLEDs, as well as other electronic devices.

The following non-limiting examples are illustrative of the invention.

### EXAMPLES

### Polymer Synthesis

The following monomers were used to synthesize polymers according to the procedures described below:

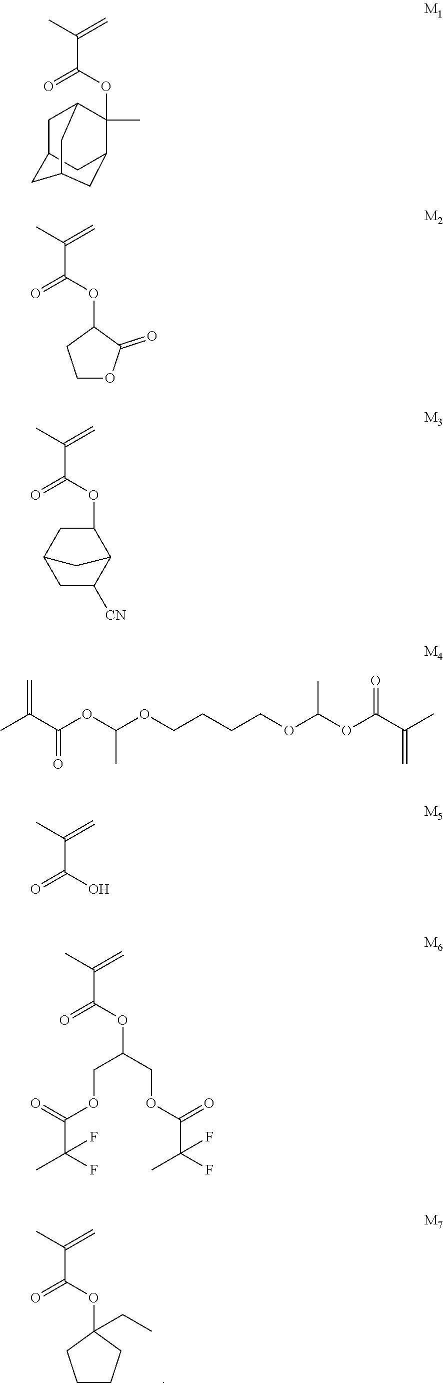

### Example 1 (Polymer P1)

5.0 g of a polymer comprising repeating units of monomers M1, M2, M3, and M4 in a molar ratio of 35/30/25/10, respectively, was dissolved with stirring in 13 g of methyl 2-hydroxyisobutyrate and 7 g of propylene glycol monomethyl ether acetate, giving a clear solution. To the stirring solution was added 0.15 g difluoroacetic acid and 0.30 g water. The mixture was warmed to 35° C. and left stirring. After 72 hours, the reaction mixture was cooled to room temperature and the polymer precipitated by adding the reaction mixture directly to 300 mL methanol. The solid was collected by filtration and dried in vacuo, affording 3.5 g of a white solid as Polymer P1. Molecular weight was determined by GPC relative to polystyrene standard and was found to be number average molecular weight (Mn)=3710 Da, weight average molecular weight (Mw)=5560 Daltons, PDI (polydispersity index)=1.5.

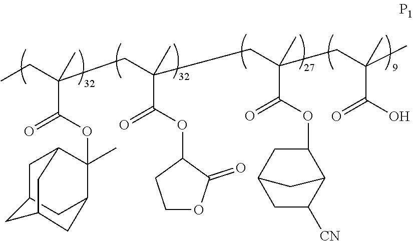

### Preparation of Photoresist Compositions

### Examples 3-5

Photoresist compositions were prepared by dissolving solid components in solvents using the materials and amounts set forth in Table 1. The resulting mixtures, made on a 16-50 g scale, were shaken on a mechanical shaker for from 3 to 24 hours and then filtered through a PTFE disk-shaped filter having a 0.2 micron pore size.

TABLE 1

| | | | | | | Enol | | |
|---|---|---|---|---|---|---|---|---|
| Example | Photoresist | P1 | P2 | PAG 1 | Q1 | Comp'd | S1 | S2 |
| Ex. 3 | PR-1 | 2.098 | 0.093 | 0.550 | 0.111 | E1/0.248 | 58.140 | 38.760 |
| Ex. 4 | PR-2 | 2.098 | 0.093 | 0.550 | 0.111 | E2/0.248 | 58.140 | 38.760 |
| Ex. 5 (Comp) | PR-3 | 2.346 | 0.093 | 0.550 | 0.111 | — | 58.140 | 38.760 |

All amounts provided as weight percent (wt %) based on total pattern trimming composition.

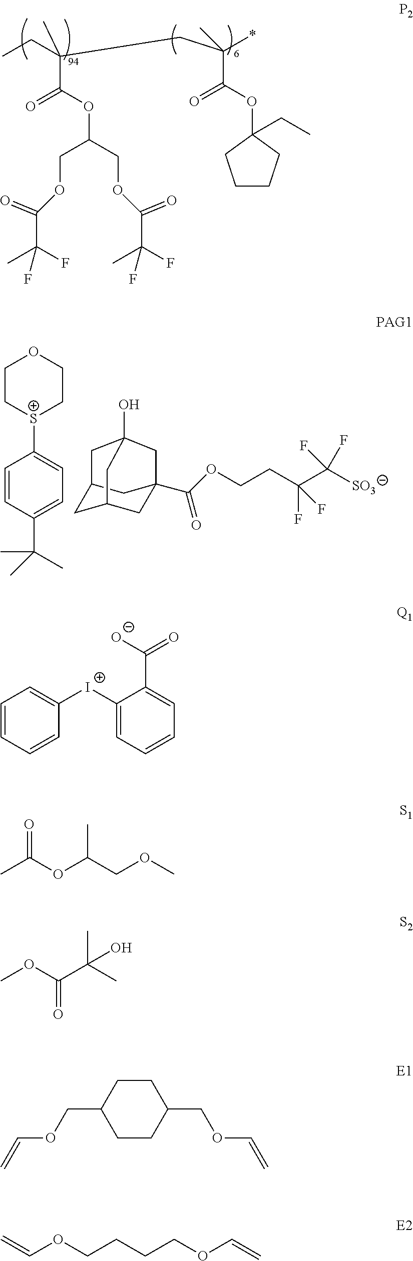

### Lithographic Evaluation

### Examples 6-8

300 mm silicon wafers were spin-coated with AR™40A antireflectant (DuPont Electronics & Imaging) using a cure temperature of 205° C. for 60 seconds to form a first BARC layer having a thickness of 800 Å. The wafers were then spin-coated with AR™104 antireflectant (DuPont Electronics & Imaging) using a cure temperature of 175° C. for 60 seconds to form a second BARC layer having a thickness of 400 Å. The wafers were then spin-coated with a respective photoresist composition prepared in Examples 3-5 and soft-baked at 110° C. for 60 seconds to provide a photoresist layer having a thickness of 900 Å. The BARC and photoresist layers were coated with a TEL Clean Track Lithius coating tool. The wafers were exposed using an ASML 1900i immersion scanner (1.3 NA, 0.86/0.61 inner/outer sigma, dipole illumination with 35Y polarization) using a mask having 1:1 line-space patterns (55 nm linewidth/110 nm pitch). The exposed wafers were post-exposure baked at 100° C. for 60 seconds and developed with a 0.26N aqueous TMAH solution for 12 seconds. The wafers were then rinsed with DI water and spun dry to form photoresist patterns. CD linewidth measurements of the formed patterns were made using a Hitachi High Technologies Co. CG4000 CD-SEM. E_{size}, which is the exposure dose at which the pattern CD is equal to the CD of the mask pattern (55 nm linewidth), was also determined. LWR was determined using a 3-sigma value from the distribution of a total of 100 arbitrary points of linewidth measurements. The results are shown in Table 2.

TABLE 2

| | Photoresist | E_{size} | LWR |
|---|---|---|---|
| Example | Composition | (mJ/cm²) | (nm) |
| Ex. 6 | PR-1 | 42 | 3.44 |
| Ex. 7 | PR-2 | 26 | 3.45 |
| Ex. 8 (Comp) | PR-3 | 27 | 4.22 |

1. A photoresist composition, comprising:
an acid-sensitive polymer comprising a first repeating unit formed from a first free radical polymerizable monomer comprising an acid-decomposable group and a second repeating unit formed from a second free radical polymerizable monomer comprising a carboxylic acid group;
a compound comprising two or more enol ether groups, wherein the compound is different from the acid-sensitive polymer;
a material comprising a base-labile group;
a photoacid generator; and
a solvent.

2. The photoresist composition of claim 1, wherein the compound is of formula (5): 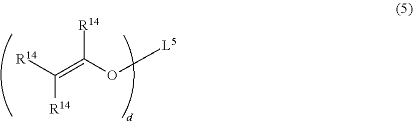
wherein: R¹⁴ independently represents —H, C₁₋₄ alkyl, or C₁₋₄ fluoroalkyl, optionally including as part of its structure one or more groups chosen from —O—, —S—, —N(R¹⁵)—, —C(O)—, —C(O)O—, or —C(O)N(R¹⁵)—, wherein R¹⁵ represents hydrogen or substituted or unsubstituted C₁₋₁₀ alkyl, and any two R¹⁴ groups together optionally forming a ring; L⁵ represents a linking group have a valency of d; and d is an integer from 2 to 4.

3. The photoresist composition of claim 2, wherein the compound is of formula (5-1):
CH₂═CH—O—R¹⁷—O—CH═CH₂ (5-1)
wherein R¹⁷ represents C₁₋₁₀ linear alkylene, C₃₋₁₀ branched alkylene, C₃₋₁₀ cyclic alkylene, or a combination thereof, each of which may be substituted or unsubstituted.

4. The photoresist composition of claim 1, wherein the compound is a polymer comprising a first repeating unit comprising an enol ether group that is pendant to a polymer backbone.

5. The photoresist composition of claim 4, wherein the first repeating unit of the compound is formed from a vinyl aromatic monomer or a (meth)acrylate monomer.

6. The photoresist composition of claim 1, wherein the acid-decomposable group is a tertiary ester group of the formula —C(═O)OC(R⁵)₃ wherein: R⁵ is each independently linear C₁₋₂₀ alkyl, branched C₃₋₂₀ alkyl, monocyclic or polycyclic C₃₋₂₀ cycloalkyl, linear C₂₋₂₀ alkenyl, branched C₃₋₂₀ alkenyl, monocyclic or polycyclic C₃₋₂₀ cycloalkenyl, monocyclic or polycyclic C₆₋₂₀ aryl, or monocyclic or polycyclic C₂₋₂₀ heteroaryl, preferably linear C₁₋₆ alkyl, branched C₃₋₆ alkyl, or monocyclic or polycyclic C₃₋₁₀ cycloalkyl, each of which is substituted or unsubstituted, each R⁵ optionally including as part of its structure one or more groups chosen from —O—, —S—, —N(R⁶)—, —C(O)—, —C(O)O—, or —C(O)N(R⁶)—, wherein R⁶ represents hydrogen or substituted or unsubstituted C₁₋₁₀ alkyl, and any two R⁵ groups together optionally forming a ring.

7. The photoresist composition of claim 1, wherein the first free radical polymerizable monomer and the second free radical polymerizable monomer are independently a vinyl aromatic monomer or a (meth)acrylate monomer.

8. The photoresist composition of claim 1, wherein the photosensitive polymer further comprises a third repeating unit comprising a lactone group.

9. The photoresist composition of claim 1, wherein the material comprising a base-labile group is a fluorinated polymer.

10. A pattern formation method, comprising:
(a) applying a layer of a photoresist composition of claim 1, on a substrate;
(b) soft-baking the photoresist composition layer;
(b) exposing the soft-baked photoresist composition layer to activating radiation;
(d) post-exposure baking the photoresist composition layer; and
(c) developing the post-exposure baked photoresist composition layer to provide a resist relief image.

11. The method of claim 10, wherein the compound is of formula (5): 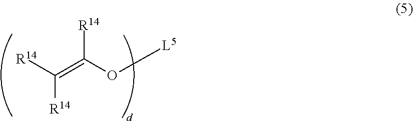
wherein: R¹⁴ independently represents —H, C₁₋₄ alkyl, or C₁₋₄ fluoroalkyl, optionally including as part of its structure one or more groups chosen from —O—, —S—, —N(R¹⁵)—, —C(O)—, —C(O)O—, or —C(O)N(R¹⁵)—, wherein R¹⁵ represents hydrogen or substituted or unsubstituted C₁₋₁₀ alkyl, and any two R¹⁴ groups together optionally forming a ring; L⁵ represents a linking group have a valency of d; and d is an integer from 2 to 4.

12. The photoresist composition of claim 11, wherein the compound is of formula (5-1):
CH₂═CH—O—R¹⁷—O—CH═CH₂ (5-1)
wherein R¹⁷ represents C₁₋₁₀ linear alkylene, C₃₋₁₀ branched alkylene, C₃₋₁₀ cyclic alkylene, or a combination thereof, each of which may be substituted or unsubstituted.

13. The photoresist composition of claim 10, wherein the compound is a polymer comprising a first repeating unit comprising an enol ether group that is pendant to a polymer backbone.

14. The photoresist composition of claim 13, wherein the first repeating unit of the compound is formed from a vinyl aromatic monomer or a (meth)acrylate monomer.

15. The photoresist composition of claim 10, wherein the acid-decomposable group is a tertiary ester group of the formula —C(═O)OC(R⁵)₃ wherein: R⁵ is each independently linear C₁₋₂₀ alkyl, branched C₃₋₂₀ alkyl, monocyclic or polycyclic C₃₋₂₀ cycloalkyl, linear C₂₋₂₀ alkenyl, branched C₃₋₂₀ alkenyl, monocyclic or polycyclic C₃₋₂₀ cycloalkenyl, monocyclic or polycyclic C₆₋₂₀ aryl, or monocyclic or polycyclic C₂₋₂₀ heteroaryl, preferably linear C₁₋₆ alkyl, branched C₃₋₆ alkyl, or monocyclic or polycyclic C₃₋₁₀ cycloalkyl, each of which is substituted or unsubstituted, each R⁵ optionally including as part of its structure one or more groups chosen from —O—, —S—, —N(R⁶)—, —C(O)—, —C(O)O—, or —C(O)N(R⁶)—, wherein R⁶ represents hydrogen or substituted or unsubstituted C₁₋₁₀ alkyl, and any two R⁵ groups together optionally forming a ring.

16. The photoresist composition of claim 10, wherein the first free radical polymerizable monomer and the second free radical polymerizable monomer are independently a vinyl aromatic monomer or a (meth)acrylate monomer.

17. The photoresist composition of claim 10, wherein the photosensitive polymer further comprises a third repeating unit comprising a lactone group.

18. The photoresist composition of claim 10, wherein the material comprising a base-labile group is a fluorinated polymer.
